(19) United States
(12) Patent Application Publication
(10) Pub. No.: US 2026/0314057 A1
(43) Pub. Date: Oct. 8, 2026

(54) SEMICONDUCTOR DEVICE INCLUDING CUTTING PATTERN

(71) Applicant: Samsung Electronics Co., Ltd., Suwon-si (KR)

(72) Inventors: Seon-Bae Kim, Suwon-si (KR); Yeongmin Jeon, Suwon-si (KR); Seunghyun Oh, Suwon-si (KR); Hyotaek Choi, Suwon-si (KR)

(73) Assignee: Samsung Electronics Co., Ltd., Suwon-si (KR)

(21) Appl. No.: 19/641,036

(22) Filed: Apr. 7, 2026

(30) Foreign Application Priority Data
Apr. 8, 2025 (KR) 10-2025-0045346

(51) Int. Cl. H10D 84/85; H10D 30/00; H10D 30/01; H10D 30/43; H10D 62/10; H10D 62/13; H10D 64/23; H10D 84/01; H10W 10/17; H10W 20/41; H10W 20/43

(52) U.S. Cl. CPC H10D 84/851; H10D 30/43; H10D 30/503; H10D 30/506; H10D 62/121; H10D 62/151; H10D 64/256; H10D 84/856; H10W 10/17; H10W 20/43; H10W 20/435; H10D 30/014; H10D 30/0191; H10D 84/0188

(57) ABSTRACT

A semiconductor device according to the disclosed concepts includes first active patterns spaced apart from one another in a first direction, a first device isolation layer between the first active patterns adjacent to one another; first channel patterns on the first active patterns, and a cutting pattern extending vertically between the first channel patterns. The cutting pattern comprises a first portion and a second portion on the first portion. A width of the first portion is greater than a width of the second portion at a boundary between the first portion and the second portion.

### CROSS-REFERENCE TO RELATED APPLICATIONS

This present application claims priority to and the benefit under 35 U.S.C. § 119(a)-(d) of Korean Patent Application No. 10-2025-0045346, filed on Apr. 8, 2025, in the Korean Intellectual Property Office, the entire disclosure of which is incorporated herein by reference.

### FIELD

The disclosed concepts relate to a semiconductor and a method for manufacturing the same, and in particular, to a semiconductor device including a field effect transistor and a method for manufacturing the same.

### BACKGROUND

Semiconductor devices may include integrated circuits including a metal oxide semiconductor field effect transistor (MOSFET). To meet an increasing demand for semiconductor devices with a small pattern size and a reduced design rule, a size of MOSFET has also been scaled down. The scale-down of the MOSFETs may lead to deterioration in operational properties of the semiconductor devices. A variety of studies are being conducted to overcome technical limitations associated with the scale-down of the semiconductor devices and to realize high performance semiconductor devices.

### SUMMARY

According to embodiments of the disclosed concepts, a semiconductor device may include first active patterns spaced apart from one another in a first direction; a first device isolation layer between the first active patterns adjacent to one another; first channel patterns on the first active patterns; and a cutting pattern extending vertically between the first channel patterns, wherein the cutting pattern comprises a first portion and a second portion on the first portion, and wherein a width of the first portion is greater than a width of the second portion at a boundary between the first portion and the second portion.

According to embodiments of the disclosed concepts, a semiconductor device may comprise a substrate including a first active region and a second active region; first active patterns spaced apart from one another in a first direction on the first active region; a first device isolation layer between the first active patterns adjacent to one another; a first gate electrode on the first active pattern; and a first cutting pattern extending through the first gate electrode into the first device isolation layer, wherein the first cutting pattern includes a first portion and a second portion on the first portion, wherein the first portion includes a first cutting layer and a second cutting layer on the first cutting layer, wherein the first cutting layer and the second cutting layer have different etch selectivities with respect to at least one etch process, and wherein a sidewall of the first portion is spaced apart from a sidewall of the second portion in the first direction.

According to embodiments of the disclosed concepts, a semiconductor device may comprise a substrate including an active pattern; a device isolation layer defining the active pattern; first channel patterns spaced apart from one another in a first direction on the active pattern; first source/drain patterns connected to the first channel patterns; a cutting pattern extending vertically between the first channel patterns adjacent to one another; a first gate electrode connected to the first source/drain patterns; a gate insulating layer interposed between the first gate electrode and each of the first channel patterns; a gate spacer on a sidewall of the first gate electrode; a gate capping pattern on an upper surface of the first gate electrode; an interlayer insulating layer on the first source/drain pattern and the gate capping pattern; an active contact connected to each of the first source/drain patterns through the interlayer insulating layer; a gate contact connected to the gate electrode through the gate capping pattern and the interlayer insulating layer; and a first metal layer on the interlayer insulating layer, the first metal layer including a first wiring connected to the active contact and the gate contact, wherein the cutting pattern includes a first portion and a second portion on the first portion, wherein the first portion includes an upper surface exposed by the second portion, and wherein a level of the upper surface of the first portion is lower than a level of an upper surface of the active pattern.

According to embodiments of the disclosed concepts, a method for manufacturing a semiconductor device may include forming first active patterns on a substrate, the first active patterns being spaced apart from one another in a first direction; forming a device isolation layer between the first active patterns adjacent to one another; forming a first channel pattern on the first active patterns; forming a sacrificial pattern covering the first channel pattern and extending in a second direction intersecting the first direction; forming a cutting hole by performing a patterning process on the sacrificial pattern; forming a first preliminary cutting layer on an inner wall of the cutting hole; forming a second preliminary cutting layer on the first preliminary cutting layer; removing the sacrificial pattern to expose a portion of a sidewall of the first preliminary cutting layer; and removing the exposed portion of the first preliminary cutting layer.

In the method for manufacturing a semiconductor device according to the disclosed concepts, the first preliminary cutting layer and the second preliminary cutting layer have different etching selectivities with respect to at least one etching process.

The method for manufacturing a semiconductor device according to the disclosed concepts further includes sequentially forming a gate insulating film and a first metal pattern on the first channel pattern before forming the sacrificial pattern.

In the method of manufacturing a semiconductor device according to the disclosed concepts, the cutting hole extends into the device isolation layer; and removing the sacrificial pattern does not remove the first preliminary cutting layer formed in the device isolation layer.

In the method for manufacturing a semiconductor device according to the disclosed concepts, the first preliminary cutting layer and the second preliminary cutting layer are formed by different deposition processes from one another.

### BRIEF DESCRIPTION OF THE DRAWINGS

FIGS. 1 to 3 are top views for describing a semiconductor device according to embodiments of the disclosed concepts.

FIG. 4 is a plan view for describing a semiconductor device according to embodiments of the disclosed concepts.

FIG. 5A is a cross-sectional view taken along line A-A′ in FIG. 4.

FIG. 5B is a cross-sectional view taken along line B-B′ of FIG. 4.

FIG. 5C is a cross-sectional view taken along line C-C′ of FIG. 4.

FIG. 5D is a cross-sectional view taken along line D-D′ of FIG. 4.

FIG. 6A is an enlarged view illustrating embodiments of a portion M of FIG. 5D.

FIG. 6B is an enlarged view illustrating embodiments of a portion N of FIG. 5D.

FIGS. 7A and 7B are enlarged views illustrating embodiments of the portion N of FIG. 5D.

FIG. 7C is an enlarged view illustrating embodiments of the portion M of FIG. 5D.

FIGS. 7D, 7E, and 7F are each enlarged views illustrating embodiments of the portion N of FIG. 5D.

FIGS. 8A, 8B, 9, 10A, 10B, 11A, 11B, 11C, 12, 13, 14A, 14B, 15A, 15B, 15C, 16A, 16B, 16C, 17A, 17B and 17C are diagrams for describing a method of manufacturing a semiconductor device according to embodiments of the disclosed concepts.

FIGS. 18A, 18B, 18C, 19A, 19B and 19C are diagrams for describing a method of manufacturing a semiconductor device according to embodiments of the disclosed concepts.

FIGS. 20 to 24 are diagrams for describing a method of manufacturing a semiconductor device according to embodiments of the disclosed concepts.

### DETAILED DESCRIPTION

Example embodiments of the disclosed concepts will now be described more fully with reference to the accompanying drawings, in which example embodiments are shown.

Embodiments of the disclosed concepts provide a semiconductor device with improved reliability and electrical characteristics.

Embodiments of the disclosed concepts provide a method for manufacturing a semiconductor element with improved reliability and electrical characteristics.

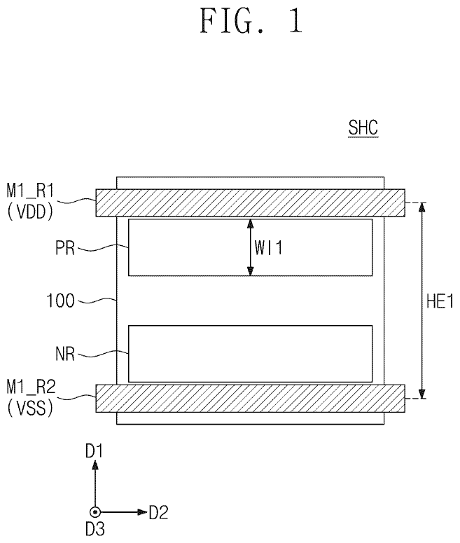

FIGS. 1 to 3 are conceptual diagrams for describing logic cells of a semiconductor device according to embodiments of the disclosed concepts.

Referring to FIG. 1, a single height cell SHC may be provided. For example, a first power wiring M1_R1 and a second power wiring M1_R2 may be provided on a substrate 100. The first power wiring M1_R1 may be a passage through which a drain voltage VDD, for example, a power voltage is provided. The second power wiring M1_R2 may be a passage through which a source voltage VSS, for example, a ground voltage is provided.

The single height cell SHC may be defined between the first power wiring M1_R1 and the second power wiring M1_R2. The single height cell SHC may include one PMOSFET region PR and one NMOSFET region NR. In other words, the single height cell SHC may have a CMOS structure provided between the first power wiring M1_R1 and the second power wiring M1_R2. A first active region may be a PMOSFET region PR, and a second active region may be an NMOSFET region NR. Conversely, the second active region may be a PMOSFET region PR, and the first active region may be an NMOSFET region NR.

Each of the PMOSFET region PR and the NMOSFET region NR may have a first width WI1 in a first direction D1. A length of the single height cell SHC in the first direction D1 may be defined as a first height HE1. The first height HE1 may be substantially equal to a distance (e.g., pitch) between the first power wiring M1_R1 and the second power wiring M1_R2.

The single height cell SHC may constitute one logic cell. A logic cell herein may refer to a logic element (e.g., AND, OR, XOR, XNOR, inverter, etc.) that performs a specific function. That is, the logic cell may include transistors for configuring logic elements and wirings connecting (e.g., electrically connecting) the transistors to one another.

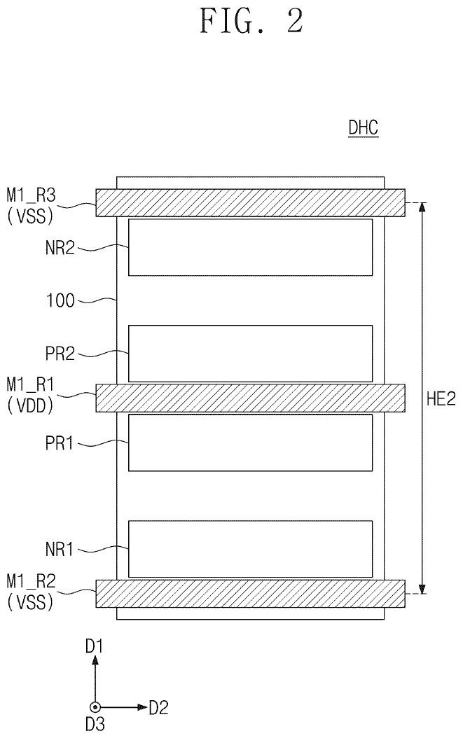

Referring to FIG. 2, a double height cell DHC may be provided. For example, the first power wiring M1_R1, the second power wiring M1_R2, and the third power wiring M1_R3 may be provided on the substrate 100. The first power wiring M1_R1 may be disposed between the second power wiring M1_R2 and the third power wiring M1_R3. The third power wiring M1_R3 may be a passage through which the source voltage VSS is provided.

The double height cell DHC may be defined between the second power wiring M1_R2 and the third power wiring M1_R3. The double height cell DHC may include a first PMOSFET region PR1, a second PMOSFET regions PR2, a first NMOSFET region NR1, and a second NMOSFET regions NR2.

A first NMOSFET region NR1 may be adjacent to the second power wiring M1_R2. A second NMOSFET region NR2 may be adjacent to the third power wiring M1_R3. Another second NMOSFET region NR2 may be adjacent to the first NMOSFET regions NR1 with the second power wiring M1_R2 interposed therebetween. First and second PMOSFET regions PR1 and PR2 may be adjacent to the first power wiring M1_R1. In a plan view, the first power wiring M1_R1 may be disposed between the first and second PMOSFET regions PR1 and PR2.

A length of the double height cell DHC in the first direction D1 may be defined as a second height HE2. The second height HE2 may be about twice the first height HE1 of FIG. 1. The first and second PMOSFET regions PR1 and PR2 of the double height cell DHC may be grouped together to operate as one PMOSFET region.

Therefore, a size of the channel of the PMOS transistor of the double height cell DHC may be larger than a size of the channels of PMOS transistors of the single height cell SHC shown above in FIG. 1. For example, the size of a channel of a PMOS transistor of a double height cell DHC may be about twice the size of the channel of the PMOS transistor of the single height cell SHC. As a result, the double height cell DHC may operate at a higher speed compared to the single height cell SHC. In the disclosed concepts, the double height cell DHC shown in FIG. 2 may be defined as a multi-height cell. A multi-height cell may include a triple height cell whose cell height is about three times that of a single height cell SHC in FIG. 1.

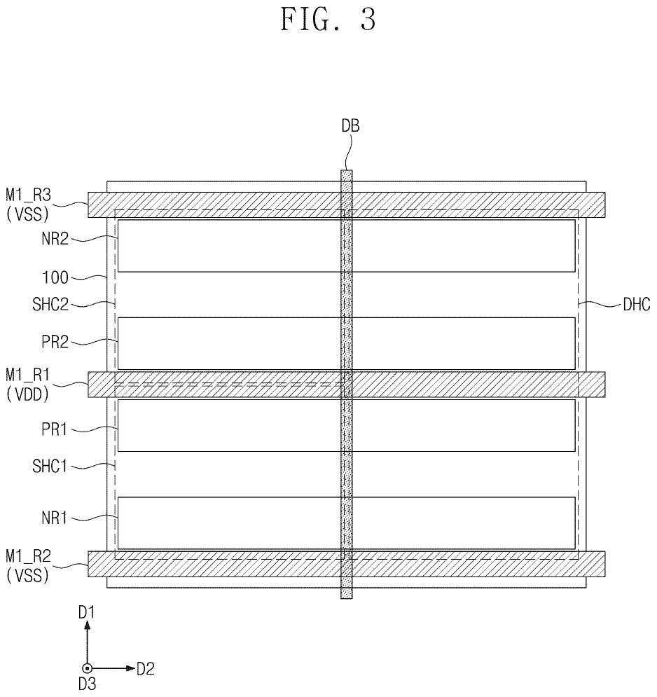

Referring to FIG. 3, a first single height cell SHC1, a second single height cell SHC2, and a double height cell DHC may be two-dimensionally disposed on the substrate 100. The first single height cell SHC1 may be disposed between the first and second power wirings M1_R1 and M1_R2. The second single height cell SHC2 may be disposed between the first and third power wirings M1_R1 and M1_R3. The second single height cell SHC2 may be adjacent to the first single height cells SHC1 in the first direction D1.

The double height cell DHC may be disposed between the second and third power wirings M1_R2 and M1_R3. The double height cell DHC may be adjacent to the first and second single height cells SHC1 and SHC2 in a second direction D2.

A separation structure DB may be provided between the first single height cell SHC1 and the double height cell DHC and between the second single height cell SHC2 and the double height cell DHC. The active region of the double height cell DHC may be electrically separated from the active region of each of the first and second single height cells SHC1 and SHC2 by the separation structure DB.

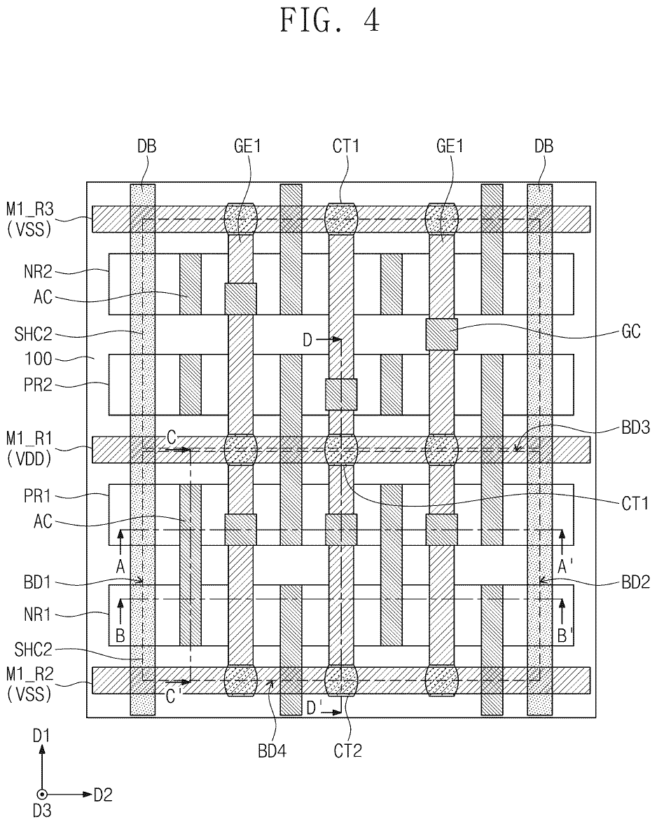

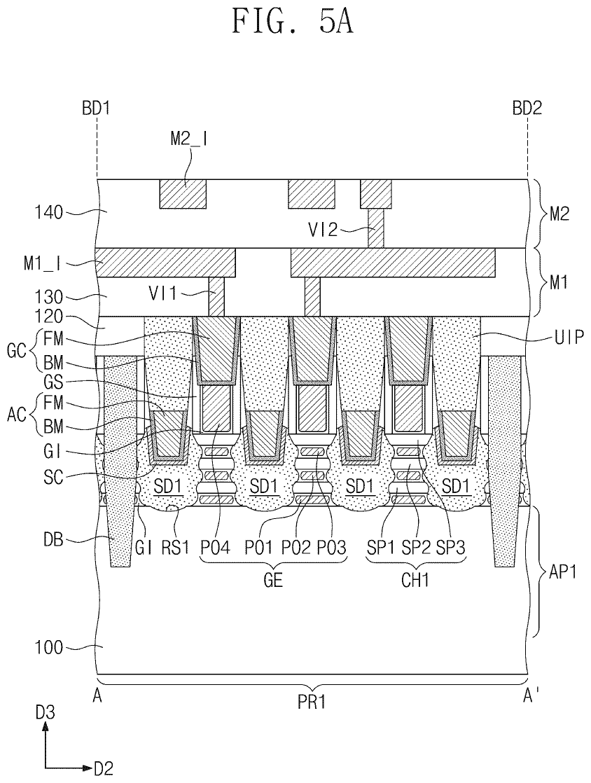

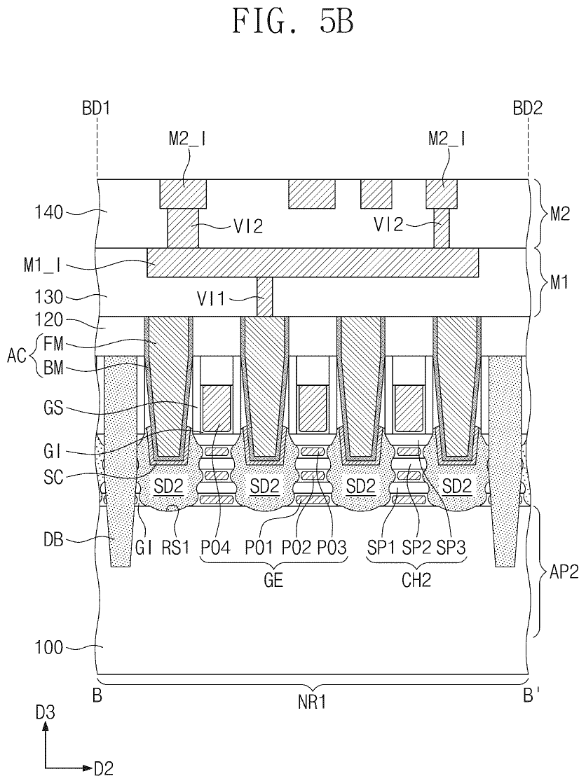

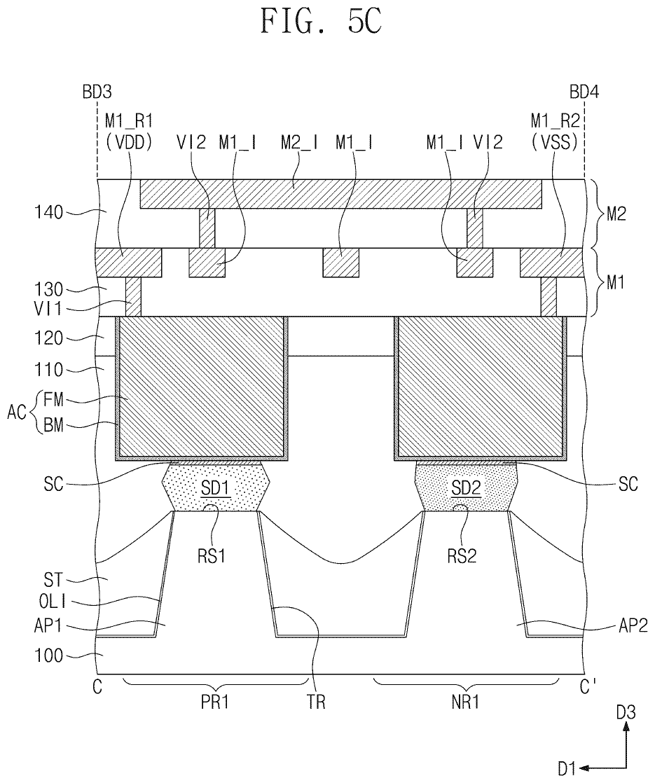

FIG. 4 is a plan view for describing a semiconductor device according to embodiments of the disclosed concepts. FIGS. 5A, 5B, 5C and 5D are cross-sectional views along line A-A′, line B-B′, line C-C′, and line D-D′ of FIG. 4, respectively. The semiconductor element illustrated in FIGS. 4 and 5A, 5B, 5C and 5D is an example in which the double height cell DHC of FIG. 2 is more specifically illustrated.

Referring to FIGS. 4 and 5A, 5B, 5C and 5D, the double height cell DHC may be provided on the substrate 100. Logic transistors constituting a logic circuit may be disposed on the double height cell DHC. The substrate 100 may be a semiconductor substrate including, for example, silicon, germanium, silicon-germanium, and/or the like, or a compound semiconductor substrate. For example, the substrate 100 may be a silicon substrate.

A first active pattern AP1 and a second active pattern AP2 may be defined by a trench TR formed on the substrate 100. The first active pattern AP1 may be provided on the first and second PMOSFET regions PR1 and PR2, and the second active pattern AP2 may be provided on first and second NMOSFET regions NR1 and NR2. The first and second active patterns AP1 and AP2 may extend in the second direction D2. The first and second active patterns AP1 and AP2 may be vertically protruding portions of the substrate 100.

A device isolation layer ST may be provided on the substrate 100. The device isolation layer ST may fill the trench TR. A liner layer OLI may be provided between the trench TR and the device isolation layer ST. The device isolation layer ST may be provided between the first active pattern AP1 and the second active pattern AP2. The device isolation layer ST may include a silicon oxide layer. The device isolation layer ST may not cover first and second channel patterns CH1 and CH2 to be described later.

A first channel pattern CH1 may be provided on the first active pattern AP1. A second channel pattern CH2 may be provided on the second active pattern AP2. Each of the first channel pattern CH1 and the second channel pattern CH2 may include a first semiconductor pattern SP1, a second semiconductor pattern SP2, and a third semiconductor pattern SP3 sequentially stacked. The first, second, and third semiconductor patterns SP1, SP2, and SP3 may be spaced apart from one another in a vertical direction (e.g., in a third direction D3).

Each of the first, second, and third semiconductor patterns SP1, SP2, and SP3 may include silicon (Si), germanium (Ge), and/or silicon-germanium (SiGe). For example, each of the first, second, and third semiconductor patterns SP1, SP2, and SP3 may include crystalline silicon. In some embodiments of the disclosed concepts, the first, second, and third semiconductor patterns SP1, SP2, and SP3 may be stacked nanosheets.

A plurality of first source/drain patterns SD1 may be provided on the first active pattern AP1. A plurality of first recesses RS1 may be formed on the first active pattern AP1. The first source/drain patterns SD1 may be provided in the first recesses RS1, respectively. The first source/drain patterns SD1 may be impurity regions of a first conductivity type (e.g., p-type). The first channel pattern CH1 may be interposed between a pair of the first source/drain patterns SD1. In other words, the first, second, and third semiconductor patterns SP1, SP2, and SP3 may connect the pair of the first source/drain patterns SD1 to one another.

A plurality of second source/drain patterns SD2 may be provided on the second active pattern AP2. A plurality of second recesses RS2 may be formed on the second active pattern AP2. The second source/drain patterns SD2 may be provided in the second recesses RS2, respectively. The second source/drain patterns SD2 may be impurity regions of a second conductivity type (e.g., n-type). The second channel pattern CH2 may be interposed between a pair of the second source/drain patterns SD2. In other words, the first, second, and third semiconductor patterns SP1, SP2, and SP3 may connect the pair of the second source/drain patterns SD2 to one another.

The first and second source/drain patterns SD1 and SD2 may be epitaxial patterns formed by a selective epitaxial growth (SEG) process. For example, an upper surface of each of the first and second source/drain patterns SD1 and SD2 may be higher than an upper surface of the third semiconductor pattern SP3. In some embodiments, the upper surface of at least one of the first or second source/drain patterns SD1 and SD2 may be located at substantially the same level as the upper surface of the third semiconductor pattern SP3.

In embodiments of the disclosed concepts, the first source/drain patterns SD1 may include a semiconductor element (e.g., SiGe) having a lattice constant greater than that of the semiconductor element of the substrate 100. Thus, the pair of first source/drain patterns SD1 may provide compressive stress to the first channel pattern CH1 therebetween. The second source/drain patterns SD2 may include the same semiconductor element (e.g., Si) as the substrate 100.

A sidewall of each of the first and second source/drain patterns SD1 and SD2 may have an uneven embossed shape. In other words, the sidewall of each of the first and second source/drain patterns SD1 and SD2 may have a wavy profile. The sidewall of each of the first and second source/drain patterns SD1 and SD2 may protrude toward first, second and third inner portions PO1, PO2, and PO3 of a gate electrode GE, which will be described later.

The gate electrodes GE extending in the first direction D1 across the first and second channel patterns CH1 and CH2 may be provided. The gate electrodes GE may be arranged in the second direction D2 according to a first pitch. Each of the gate electrodes GE may vertically overlap the first and second channel patterns CH1 and CH2.

The gate electrode GE may include a first inner portion PO1 interposed between the first and second active patterns AP1 or AP2 and the first semiconductor pattern SP1, a second inner portion PO2 interposed between the first semiconductor pattern SP1 and the second semiconductor pattern SP2, a third inner portion PO3 interposed between the second semiconductor pattern SP2 and the third semiconductor pattern SP3, and a fourth inner portion PO4 on the third semiconductor pattern SP3.

Referring to FIG. 5D, the gate electrode GE may be provided on an upper surface, a lower surface, and both sidewalls of each of the first, second, and third semiconductor patterns SP1, SP2, and SP3. In other words, the transistor according to the present embodiment may be a three-dimensional field effect transistor (e.g., Multi-Bridge-Channel (MBC) FET or Gate-All-Around (GAA) FET) in which the gate electrode GE three-dimensionally surrounds the channel (e.g., the first channel pattern CH1 and the second channel pattern CH2).

Referring to FIGS. 4, 5A, 5B, 5C and 5D, a pair of gate spacers GS may be disposed on both sidewalls of the fourth inner portion PO4 of the gate electrode GE, respectively. The gate spacers GS may extend in the first direction D1 along the gate electrode GE. Upper surfaces of the gate spacers GS may be higher than upper surfaces of the gate electrode GE. In some embodiments, the gate spacers GS may include at least one of SiCN, SiCON, or SiN. In some embodiments, the gate spacers GS may include a multi-layer composed of at least two of SiCN, SiCON, or SiN.

A gate capping pattern GP may be provided on the gate electrode GE. The gate capping pattern GP may extend in the first direction D1 along the gate electrode GE. The gate capping pattern GP may include a material having etching selectivity with respect to the first and second interlayer insulating layers 110 and 120 to be described later. For example, the gate capping pattern GP may include SiON, SiCN, SiCON, and/or SiN.

A gate insulating layer GI may be interposed between the gate electrode GE and the first channel pattern CH1 and between the gate electrode GE and the second channel pattern CH2. The gate insulating layer GI may be on the upper surface, the bottom surface, and both sidewalls of each of the first, second, and third semiconductor patterns SP1, SP2, and SP3. The gate insulating layer GI may be on the upper surface of the device isolation layer ST under the gate electrode GE.

In embodiments of the disclosed concepts, the gate insulating layer GI may include a silicon oxide layer, a silicon oxynitride layer, and/or a high dielectric layer HK. The high dielectric layer HK may be interposed between the gate electrode GE and the gate insulating layer GI. The high dielectric layer HK may surround inner gate electrodes IGE1, IGE2, and IGE3 of the gate electrode GE with a uniform thickness. The high dielectric layer HK may extend from the lower surface to a sidewall of a outer gate electrode OGE of the gate electrode GE. For example, the gate insulating layer GI may have a structure stacked on the high dielectric layer HK.

The high dielectric layer HK may include a high dielectric constant material having a higher dielectric constant than that of the silicon oxide layer. For example, the high dielectric layer HK may include hafnium oxide, hafnium silicon oxide, hafnium zirconium oxide, hafnium tantalum oxide, lanthanum oxide, zirconium dioxide, zirconium silicon dioxide, tantalum dioxide, titanium dioxide, barium strontium titanium oxide, barium titanium oxide, strontium aluminum oxide, lithium oxide, aluminum oxide, lead scandium tantalum oxide, and/or lead zinc niobate.

Referring to FIGS. 4, 5A, 5B, 5C and 5D, the gate electrode GE may include a first metal pattern MP1 and a second metal pattern MP2 on the first metal pattern MP1. The first metal pattern MP1 may be provided on the gate insulating layer GI to be adjacent to the first, second, and third semiconductor patterns SP1, SP2, and SP3. The first metal pattern MP1 may include a work function metal that adjusts a threshold voltage of the transistor. By adjusting a thickness and a composition of the first metal pattern MP1, a desired threshold voltage of the transistor can be achieved. For example, the first, second, and third inner portions PO1, PO2, and PO3 of the gate electrode GE may be formed of the first metal pattern MP1 that is a work function metal. The fourth inner portion PO4 of the gate electrode GE may also include the first metal pattern MP1.

The first metal pattern MP1 may include a metal nitride layer. For example, the first metal pattern MP1 may include at least one metal from among titanium (Ti), tantalum (Ta), aluminum (Al), tungsten (W), and/or molybdenum (Mo) and nitrogen (N). Further, the first metal pattern MP1 may further include carbon (C). The first metal pattern MP1 may include a plurality of stacked work function metal layers.

The second metal pattern MP2 may include a metal having lower resistance than the first metal pattern MP1. For example, the second metal pattern MP2 may include at least one metal from among tungsten (W), aluminum (Al), titanium (Ti), and/or tantalum (Ta). For example, the fourth inner portion PO4 of the gate electrode GE may include the first metal pattern MP1 and the second metal pattern MP2 on the first metal pattern MP2.

Referring to FIGS. 4, 5A, 5B, and 5D, the single height cell SHC may have a first boundary BD1 and a second boundary BD2 that are opposite to one another in the second direction D2. The first and second boundaries BD1 and BD2 may extend in the first direction D1. The single height cell SHC may have a third boundary BD3 and a fourth boundary BD4 that are opposite to one another in the first direction D1. The third and fourth boundaries BD3 and BD4 may extend in the second direction D2.

Cutting patterns CT may be disposed on a boundary parallel to the second direction D2 of each of the first and second single height cells SHC1 and SHC2. For example, the cutting patterns CT may be disposed on the third and fourth boundaries BD3 and BD4 of the first single height cell SHC1. The cutting patterns CT may be arranged at the first pitch along the third boundary BD3. The cutting patterns CT may be arranged at the first pitch along a fourth boundary BD4. In a plan view, the cutting patterns CT on the third and fourth boundaries BD3 and BD4 may be disposed to overlap on the gate electrodes GE, respectively.

The cutting patterns CT may extend in the third direction D3 from the device isolation layer ST to the gate capping pattern GP. A level of an upper surface of the cutting pattern CT may be the same as or higher than a level of an upper surfaces of the gate electrodes GE. The cutting pattern CT may include an insulating material such as a silicon nitride layer, a silicon oxide layer, and/or a combination thereof.

The gate electrode GE on the first single height cell SHC1 may be separated from the gate electrode GE on the second single height cells SHC2 by the cutting pattern CT. The cutting pattern CT may be interposed between the gate electrode GE on the first single height cell SHC1 and the gate electrode GE on the second single height cell SHC2 aligned with it in the first direction D1. In other words, the gate electrode GE extending in the first direction D1 may be separated into a plurality of gate electrodes GE by the cutting patterns CT.

The cutting patterns CT may include a first cutting pattern CT1 on the PMOSFET region PR and a second cutting pattern CT2 on the NMOSFET region NR. The first cutting pattern CT1 may be located between the first PMOSFET region PR 1 and the second PMOSFET region PR2. The second cutting pattern CT2 may be located between the first NMOSFET region NR1 and the second NMOSFET region NR2.

A first interlayer insulating layer 110 may be provided on the substrate 100. The first interlayer insulating layer 110 may extend around the gate spacers GS and the first and second source/drain patterns SD1 and SD2. A second interlayer insulating layer 120 covering the gate capping pattern GP may be disposed on the first interlayer insulating layer 110. A third interlayer insulating layer 130 may be provided on the second interlayer insulating layer 120. A fourth interlayer insulating layer 140 may be provided on the third interlayer insulating layer 130. For example, the first, second, third and fourth interlayer insulating layers 110, 120, 130 and 140 may include a silicon oxide layer.

A pair of separation structures DB facing one another in the second direction D2 may be provided on both sides of each of the first and second single height cells SHC1 and SHC2. For example, the pair of separation structures DB may be provided on the first and second boundaries BD1 and BD2, respectively, of the first and second single height cells SHC1 and SHC2. The separation structure DB may extend parallel to the gate electrodes GE in the first direction D1. A pitch between the separation structure DB and the gate electrode GE adjacent thereto may be the same as the first pitch.

The separation structure DB may extend through the first interlayer insulating layer 110 into the first and second active patterns AP1 and AP2. The separation structure DB may penetrate an upper portion of each of the first and second active patterns AP1 and AP2. The separation structure DB may electrically separate the active region of the single height cell SHC from the active region of another adjacent cell.

Active contacts AC may be provided that penetrate the first and second interlayer insulating layers 110 and 120 and may be electrically connected to the first and second source/drain patterns SD1 and SD2, respectively. A pair of active contacts AC may be provided on both sides of the gate electrode GE, respectively. In a plan view, the active contact AC may have a bar shape extending in the first direction D1.

The active contact AC may be a self-aligned contact. In other words, the active contact AC may be formed in a self-aligned manner using the gate capping pattern GP and the gate spacer GS. For example, the active contact AC may be on at least a portion of a sidewall of the gate spacer GS. The active contact AC may be on a portion of the upper surface of the gate capping pattern GP.

A metal-semiconductor compound layer SC, for example, a silicide layer, may be interposed between the active contact AC and the first source/drain pattern SD1, and between the active contact AC and the second source/drain patterns SD2, respectively. The active contact AC may be electrically connected to the first and second source/drain patterns SD1 and SD2 through the metal-semiconductor compound layer SC. For example, the metal-semiconductor compound layer SC may include titanium-silicide, tantalum-silicide, tungsten-silicide, nickel-silicide, and/or cobalt-silicide.

Gate contacts GC electrically may penetrate or extend into the second interlayer insulating layer 120 and the gate capping pattern GP to be connected to the gate electrodes GE. In a plan view, the gate contacts GC may be disposed to overlap the PMOSFET region PR and the NMOSFET region NR, respectively. For example, the gate contact GC may be provided on the first active pattern AP1.

In some embodiment of the disclosed concepts, referring to FIG. 5A, an upper portion of the active contact AC adjacent to the gate contact GC may be filled with an upper insulating pattern UIP. A lower surface of the upper insulating pattern UIP may be lower than the lower surface of the gate contact GC. In other words, an upper surface of the active contact AC adjacent to the gate contact GC may be lower than the lower surface of the gate contact GC by the upper insulating pattern UIP. Accordingly, it is possible to prevent a short circuit from occurring when the gate contact GC comes into contact with the active contact AC adjacent thereto.

Each of the active contact AC and the gate contact GC may include a conductive pattern FM and a barrier pattern BM surrounding the conductive pattern FM. For example, the conductive pattern FM may include aluminum, copper, tungsten, molybdenum, and/or cobalt. The barrier pattern BM may be on sidewalls and a lower surface of the conductive pattern FM. The barrier pattern BM may include a metal layer/metal nitride layer. The metal layer may include titanium, tantalum, tungsten, nickel, cobalt, and/or platinum. The metal nitride layer may include a titanium nitride layer TiN, a tantalum nitride layer TaN, a tungsten nitride layer WN, a nickel nitride layer NiN, a cobalt nitride layer CoN, and/or a platinum nitride layer PtN.

A first metal layer M1 may be provided in the third interlayer insulating layer 130. For example, the first metal layer M1 may include the first power wiring M1_R1, the second power wiring M1_R2, and first wirings M1_I. Each of the wirings M1_R1, M1_R2, and M1_I of the first metal layer M1 may extend parallel to one another in the second direction D2.

Specifically, the first and second power wirings M1_R1 and M1_R2 may be provided on the third and fourth boundaries BD3 and BD4, respectively, of the first single height cell SHC1. The first power wiring M1_R1 may extend in the second direction D2 along the third boundary BD3. The second power wiring M1_R2 may extend in the second direction D2 along the fourth boundary BD4. The third power wiring M1_R3 may extend in the second direction D2 on the second single height cell SHC2 to be parallel to the first and second power wirings M1_R1 and M1_R2.

The first wirings M1_I of the first metal layer M1 may be disposed between the first and second power wirings M1_R1 and M1_R2. The first wirings M1_I of the first metal layer M1 may be arranged along the first direction D1 at a second pitch. The second pitch may be smaller than the first pitch. A line width of each of the first wirings M1_I may be smaller than a line width of each the first and second power wirings M1_R1 and M1_R2.

The first metal layer M1 may further include first vias VI1. The first vias VI1 may be provided under the wirings M1_R1, M1_R2, and M1_I of the first metal layer M1, respectively. The active contact AC and the wirings of the first metal layer M1 may be electrically connected to one another through the first via VI1. The gate contact GC and the wirings of the first metal layer M1 may be electrically connected to one another through the first via VI1.

The wirings of the first metal layer M1 and the first via VI1 thereunder may each be formed in a separate process from one another. In some embodiments, each of the wirings of the first metal layer M1 and the first via VI1 may be formed in a single damascene process. The semiconductor device according to the present embodiment may be formed using a process of less than 20 nm.

A second metal layer M2 may be provided in the fourth interlayer insulating layer 140. The second metal layer M2 may include a plurality of second wirings M2_I. Each of the second wirings M2_I of the second metal layer M2 may have a line shape or a bar shape extending in the first direction D1. In other words, the second wirings M2_I may extend parallel to one another in the first direction D1.

The second metal layer M2 may further include second vias VI2 respectively provided under the second wirings M2_I. The wirings of the first metal layer M1 and the wirings of the second metal layer M2 may be electrically connected to one another through the second via VI2. For example, the wirings of the second metal layer M2 and the second via VI2 thereunder may be formed together through a dual damascene process.

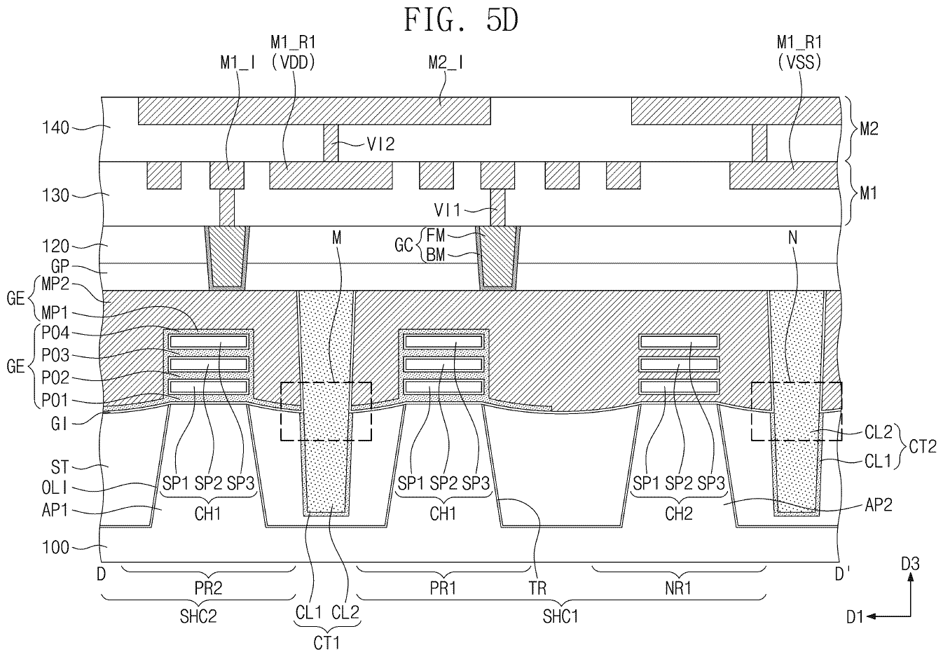

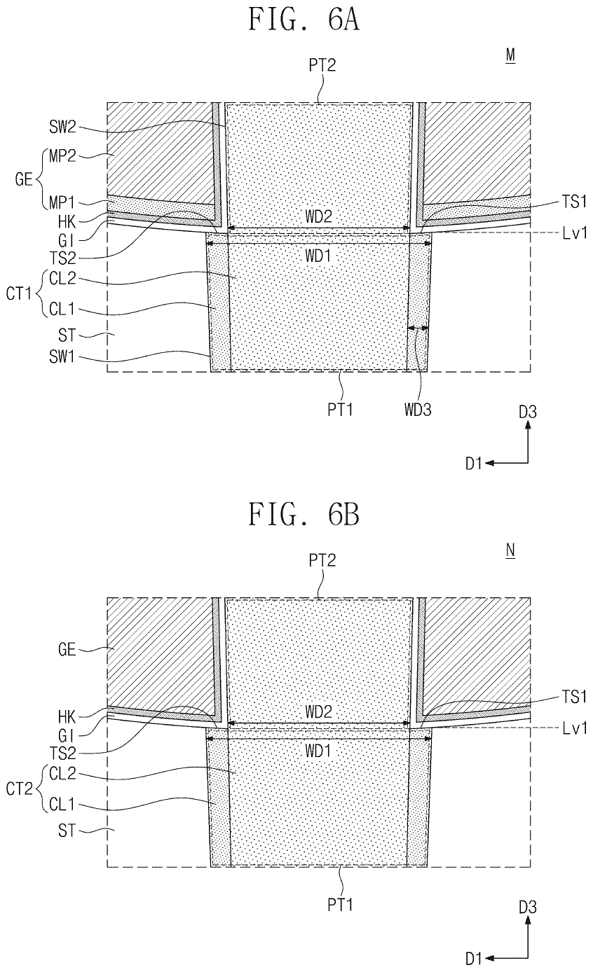

The wirings of the first metal layer M1 and the wirings of the second metal layer M2 may include the same or different conductive materials. For example, the wirings of the first metal layer M1 and the wirings of the second metal layer M2 may include at least one metal material selected from aluminum, copper, tungsten, molybdenum, ruthenium, and/or cobalt. Metal layers (e.g., M3, M4, M5 . . . ) stacked on the fourth interlayer insulating layer 140 may be further disposed. Each of the stacked metal layers may include wirings for routing between cells. FIG. 6A is an enlarged view illustrating embodiments of the portion M of FIG. 5D. FIG. 6B is an enlarged view illustrating embodiments of the portion N of FIG. 5D. The cutting pattern CT will be described in more detail with reference to FIGS. 6A and 6B.

Referring to FIG. 6A, the first cutting pattern CT1 may include a first portion PT1 and a second portion PT2 on the first portion PT1. Based on a boundary at which a width of the first cutting pattern CT1 changes abruptly, a lower portion of the boundary may be the first portion PT1 and an upper portion of the boundary is the second portion PT2. For example, the first portion PT1 may be a portion of the first cutting pattern CT1 embedded in the device isolation layer ST, and the second portion PT2 may be a portion other than the first portion PT1, but is not limited thereto.

The device isolation layer ST may cover sidewalls and a lower surface of the first portion PT1. The gate insulating layer GI may be provided on the first and second upper surfaces TS1 and TS2 to be described later of the first portion PT1 and sidewalls of the second portion PT2. The high dielectric layer HK may be provided on the gate insulating layer GI. Since the first cutting pattern CT1 is located on the PMOSFET region PR, the first metal pattern MP1 may be further provided on the high dielectric layer HK. The first metal pattern MP1 may extend in the first direction D1 on the high dielectric layer HK. The first metal pattern MP1 is provided only on a lower portion of a sidewall of the second portion PT2, and may not extend in the third direction D3 along the sidewall of second portion PT2.

At the boundary between the first portion PT1 and the second portion PT2, a first width WD1 of the first portion PT1 may be greater than a second width WD2 of the second portion PT2. At the boundary of the second portion PT2 and the first portion PT1, the width of the first cutting pattern CT1 may change discontinuously. The width of the first cutting pattern CT1 may abruptly decrease from the first width WD1 of the first portion PT1 to the second width WD2 of the second portion PT2.

A width of an upper portion of the first portion PT1 may be greater than a width of a lower portion of the second portion PT2. Therefore, a sidewall SW1 of the first portion PT1 may be spaced apart from a sidewall SW2 of the second portion PT2 in the first direction D1. The sidewall SW1 of the first portion PT1 may be offset in the first direction D1 with respect to the sidewall SW2 of the second portion PT2.

The first portion PT1 may include a first upper surface TS1 and a second upper surface TS2 exposed by the second portion PT2. The second portion PT2 may be located between the first upper surface TS1 and the second upper surface TS2. The first upper surface TS1 and the second upper surface TS2 may be spaced apart from one another in the first direction D1 with the second portion PT2 interposed therebetween. The first upper surface TS1 and the second upper surface TS2 may be upper surfaces of a first cutting layer CL1 to be described later. The first upper surface TS1 and the second upper surface TS2 may extend in a direction parallel to the substrate 100 (for example, the first direction D1), but are not limited thereto.

The first upper surface TS1 and the second upper surface TS2 may be stepped surfaces of the first cutting pattern CT1. In other words, the width of the first cutting pattern CT1 may change due to the first upper surface TS1 and the second upper surface TS2. The first upper surface TS1 and the second upper surface TS2 may connect a sidewall of the first portion PT1 and a sidewall of the second portion PT2. At the boundary between the first portion PT1 and the second portion PT2, a difference in the width of the second portion PT2 and the width of the first portion PT1 may be substantially equal to a sum of lengths of the first upper surface TS1 and the second upper surface TS2.

The gate insulating layer GI and the high dielectric layer HK may be sequentially provided on the first upper surface TS1 and the second upper surface TS2. The first upper surface TS1 and the second upper surface TS2 may be in contact with the gate insulating layer GI. The first upper surface TS1 and the second upper surface TS2 may face the gate electrode GE.

Referring to FIGS. 5D and 6A, a level of the first upper surface TS1 and a level of the second upper surface TS2 may be a first level Lv1. The first level Lv1 may be lower than a level of an upper surface of the first active pattern AP1. In some embodiments, the level of the first upper surface TS1 and the level of the second upper surface TS2 may be different from one another. For example, the level of the first upper surface TS1 may be higher than the level of the second upper surface TS2.

The first portion PT1 may include a first cutting layer CL1 and a second cutting layer CL2 on the first cutting layer CL1. The first cutting layer CL1 may cover both sidewalls and a lower surface of the second cutting layer CL2. The first cutting layer CL1 may be interposed between the second cutting layer CL2 and the device isolation layer ST. A third width WD3 of the first cutting layer CL1 in the first direction D1 may be smaller than a width of the second cutting layer CL2 in the first direction D1.

The first cutting layer CL1 and the second cutting layer CL2 may have different etch selectivity for at least one etching process. The etching process may be, but is not limited to, a wet etch process. For example, the first cutting layer CL1 and the second cutting layer CL2 may include silicon nitride (SiN), but may have different etching selectivity for the wet etching process. The first cutting layer CL1 and the second cutting layer CL2 may be formed by different deposition processes. The first cutting layer CL1 and the second cutting layer CL2 may include the same material, but may have different etching selectivity for the etching process depending on different deposition processes, differences in chemical composition, whether heat treatment is performed, and the like.

For example, the first cutting layer CL1 and the second cutting layer CL2 may include silicon nitride (SiN), and the first cutting layer CL1 may have lower density or lower crystallinity than the second cutting layer CL2. For this reason, the first cutting layer CL1 may be etched more by the wet etching process than the second cutting layer CL2.

The first cutting layer CL1 and the second cutting layer CL2 may include materials that have different etching selectivities from one another with respect to the etching process. The first cutting layer CL1 and the second cutting layer CL2 may include different materials. The first cutting layer CL1 and the second cutting layer CL2 may include an insulating material such as a silicon nitride layer, a silicon oxide layer, and/or a combination thereof.

An upper surface of the first cutting layer CL1 may be the first upper surface TS1 and the second upper surface TS2 of the first portion PT1. A level of the upper surface of the first cutting layer CL1 may be lower than a level of the upper surface of the first active pattern AP1. The upper surface of the first cutting layer CL1 may be located at a lower level than an upper surface of the second cutting layer CL2. The first cutting layer CL1 may include an upper surface exposed by the second cutting layer CL2. The upper surface of the first cutting layer CL1 may face the gate electrode GE.

At the boundary between the first portion PT1 and the second portion PT2, the difference between the width of the second portion PT2 and the width of the first portion PT1 may be substantially equal to the length of the upper surface of the first cutting layer CL1. The second width WD2 of the second portion PT2 may be different from the first width WD1 of the first portion PT1 by the first cutting layer CL1.

Referring to FIG. 6B, the second cutting pattern CT2 may be substantially the same as the first cutting pattern CT1. However, since the second cutting pattern CT2 is provided on the NMOSFET region NR, the gate electrode GE may not include the first metal pattern MP1. Accordingly, the first metal pattern MP1 may be omitted on the high dielectric layer HK.

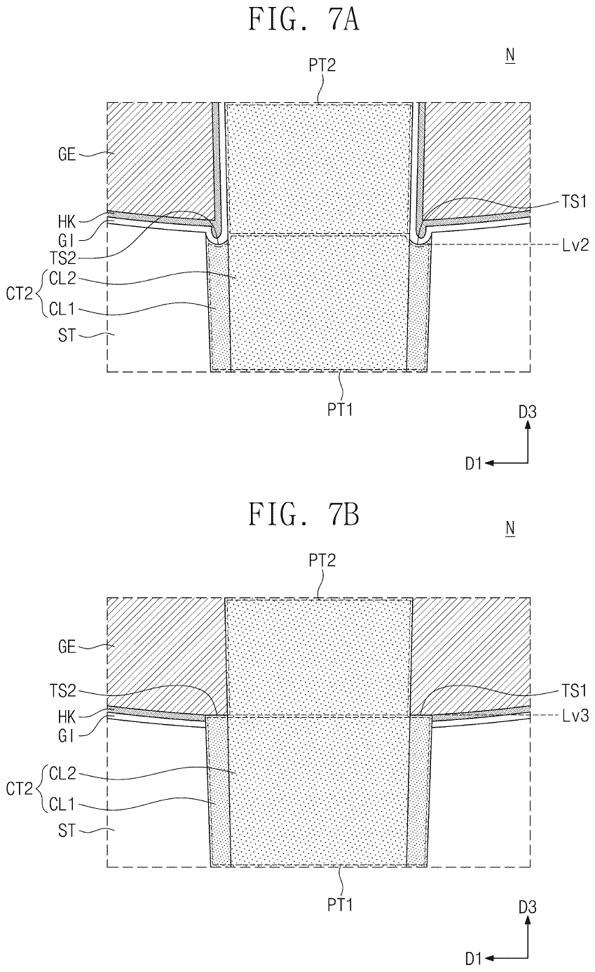

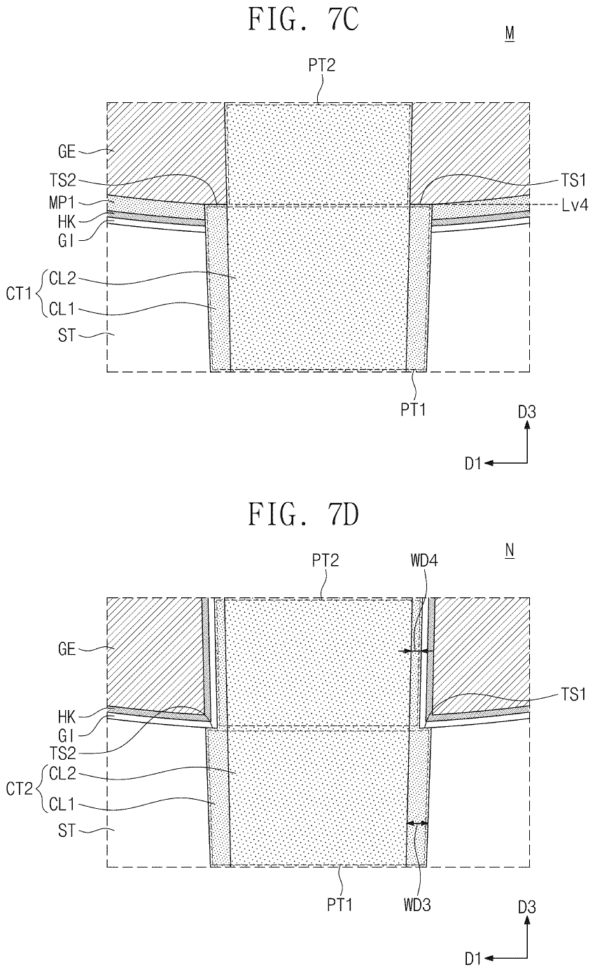

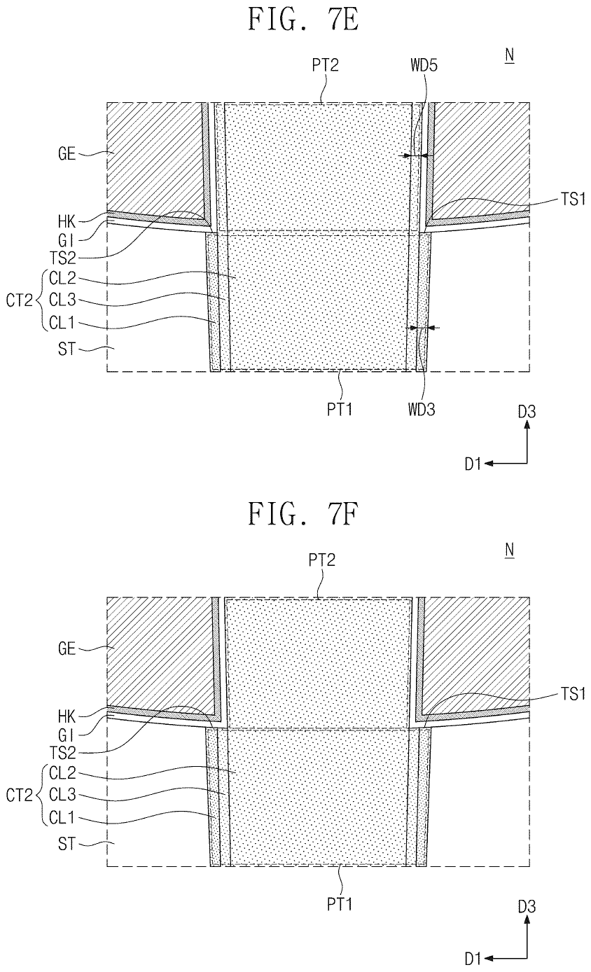

FIGS. 7A and 7B are enlarged views illustrating embodiments of the portion N of FIG. 5D. Except for technical features that overlap with those described with reference to FIGS. 6A and 6B, differences will be described in detail. The second cutting pattern CT2 according to FIGS. 7A and 7B may be equally applied to the first cutting pattern CT1 of FIG. 6A, except that there is no first metal pattern MP1.

Referring to FIG. 7A, the first upper surface TS1 and the second upper surface TS2 may be curved surfaces recessed inward of the first portion PT1. The first upper surface TS1 and the second upper surface TS2 may be concave curved surfaces. This is because the first cutting layer CL1 is etched deeper than the upper surface of the device isolation layer ST in the manufacturing method to be described later. The level of the first upper surface TS1 and the level of the second upper surface TS2 may be a second level Lv2, which may be lower than the first level Lv1 of FIGS. 6A and 6B. Accordingly, the second level Lv2 of each of the first upper surface TS1 and the second upper surface TS2 may be lower than the level of the upper surface of the device isolation layer ST.

The gate insulating layer GI and the high dielectric layer HK may be provided on the first upper surface TS1 and the second upper surface TS2. A bottom surface of the gate insulating layer GI in contact with the first upper surface TS1 and the second upper surface TS2 may be located on a lower level than the upper surface of the device isolation layer ST.

Referring to FIG. 7B, the first upper surface TS1 and the second upper surface TS2 of the first portion PT1 may be located at a third level Lv3, and the third level Lv3 may be higher than the first level Lv1. The first upper surface TS1 and the second upper surface TS2 may be positioned at a higher level than the upper surface of the device isolation layer ST. In other words, the level of the upper surface of the first cutting layer CL1 may be higher than the level of the upper surface of the device isolation layer ST.

The gate insulating layer GI and the high dielectric layer HK may be in contact with the sidewall of the first portion PT1. In other words, the gate insulating layer GI and the high dielectric layer HK may be in contact with the sidewall of the first cutting layer CL1. The gate insulating layer GI may not be provided on the first upper surface TS1 and the second upper surface TS2 of the first portion PT1. Therefore, the first upper surface TS1 and the second upper surface TS2 may be in direct contact with the gate electrode GE. The gate insulating layer GI may not be provided on the sidewall of the second portion PT2.

In some embodiments, the first upper surface TS1 and the second upper surface TS2 may be positioned at a higher level than the upper surface of the gate insulating layer GI and the upper surface of a high dielectric layer HK. Therefore, a portion of the sidewall of the first cutting layer CL1 may be in contact with the gate electrode GE.

FIG. 7C is an enlarged view illustrating embodiments of the portion M of FIG. 5D. Except for technical features that overlap with those described with reference to FIG. 6A, differences are described in detail.

Referring to FIG. 7C, the first upper surface TS1 and the second upper surface TS2 may be located at a fourth level Lv4, and the fourth level Lv4 may be higher than the first level Lv1 and the third level Lv3. The first upper surface TS1 and the second upper surface TS2 may be positioned at a higher level than the upper surface of the device isolation layer ST, the upper surface of a gate insulating layer GI, and the upper surface of the high dielectric layer HK. In other words, the level of the upper surface of the first cutting layer CL1 may be located at a higher level than the upper surface of a device isolation layer ST, the upper surface of gate insulating layer GI, and the upper surface of high dielectric layer HK. This is because the gate insulating layer GI, the high dielectric layer HK, and the first metal pattern MP1 are formed earlier than the first cutting pattern CT1 in the manufacturing process to be described later.

The first upper surface TS1 and the second upper surface TS2 may be substantially coplanar with the upper surface of the first metal pattern MP1, but are not limited thereto. In some embodiments, the upper surface of the first upper surface TS1 and the upper surface of the second upper surface TS2 may be located at a lower or higher level than the upper surface of the first metal pattern MP1. When the first upper surface TS1 and the second upper surface TS2 are located at a higher level than the upper surface of the first metal pattern MP1, a portion of the sidewall of the first cutting layer CL1 may be in contact with the second metal pattern MP2.

The gate insulating layer GI, the high dielectric layer HK, and the first metal pattern MP1 may be in contact with the sidewall of the first portion PT1. In other words, the gate insulating layer GI, the high dielectric layer HK, and the first metal pattern MP1 may be in contact with the first cutting layer CL1. The first cutting layer CL1 may be interposed between the second cutting layer CL2 and each of the gate insulating layer GI, the high dielectric layer HK, and the first metal pattern MP1.

FIGS. 7D, 7E, and 7F are each enlarged views illustrating embodiments of the portion N of FIG. 5D. Except for technical features that overlap with those described with reference to FIGS. 6A and 6B, differences are described in detail. The second cutting pattern CT2 according to FIGS. 7D, 7E, and 7F may be equally applied to the first cutting pattern CT1 of FIG. 6A, except that there is no first metal pattern MP1.

Referring to FIG. 7D, the second portion PT2 may further include a first cutting layer CL1 on the second cutting layer CL2. The first cutting layer CL1 of the second portion PT2 may be on both sidewalls of the second cutting layer CL2 of the second portion PT2. A fourth width WD4 of the first cutting layer CL1 of the second portion PT2 in the first direction D1 may be smaller than the third width WD3 of the first cutting layer CL1 of the first portion PT1. Due to the first cutting layer CL1 of the second portion PT2, the lengths of the first upper surface TS1 and the second upper surface TS2 may decrease, but are not limited thereto.

In some embodiments, the first cutting layer CL1 of the second portion PT2 may be provided only on a portion of a sidewall of the second cutting layer CL2. For this reason, the first cutting layer CL1 may be provided on any part of the sidewall of the second cutting layer CL2, and the first cutting layer CL1 may not be provided on the other part.

The first cutting layer CL1 of the second portion PT2 may be interposed between the second cutting layer CL2 and the gate electrode GE. The gate insulating layer GI and the high dielectric layer HK may be interposed between the first cutting layer CL1 and the gate electrode GE, but are not limited thereto. As shown in FIG. 7B, the gate insulating layer GI and the high dielectric layer HK may not be provided on the sidewall of the second portion PT2.

Referring to FIG. 7E, the first portion PT1 may further include a third cutting layer CL3 between the first cutting layer CL1 and the second cutting layer CL2. The third cutting layer CL3 may extend in the third direction D3 along the sidewall of the second cutting layer CL2. For this reason, the second portion PT2 may further include the third cutting layer CL3 on the sidewall of the second cutting layer CL2. A fifth width WD5 of the third cutting layer CL3 may be smaller than or greater than the third width WD3 of the first cutting layer CL1, but is not limited thereto. The fifth width WD5 of the third cutting layer CL3 may be the same as the third width WD3 of the first cutting layer CL1.

Referring to FIG. 7F, the first portion PT1 may further include the third cutting layer CL3 between the first cutting layer CL1 and the second cutting layer CL2, but the second portion PT2 may not include the third cutting layer CL3.

The upper surface of the first cutting layer CL1 and an upper surface of the third cutting layer CL3 may be the first and second upper surfaces TS1 and TS2 of the first portion PT1. The upper surface of the first cutting layer CL1 and the upper surface of the third cutting layer CL3 may be coplanar, but are not limited thereto. In some embodiments, the upper surface of the first cutting layer CL1 may be located at a different level from the upper surface of a third cutting layer CL3.

Referring to FIGS. 7E and 7F, the third cutting layer CL3 may have a different etch selectivity than that of at least one of the first cutting layer CL1 or the second cutting layer CL2 for at least one etching process. According to FIG. 7E, the third cutting layer CL3 may have an etching selectivity different from that of the first cutting layer CL1 with respect to the etching process. According to FIG. 7F, the third cutting layer CL3 may have an etching selectivity different from that of the second cutting layer CL2. In some embodiments, the third cutting layer CL3 may have a different etching selectivity for each of the first cutting layer CL1 and the second cutting layer CL2.

For example, all of the first, second, and third cutting layers CL1, CL2, and CL3 include silicon nitride (SiN), and may have different etching selectivities for the wet etching process. The third cutting layer CL3 may be formed by a deposition process different from that used for at least one of the first or second cutting layers CL1 or CL2. The third cutting layer CL3 may include the same material as at least one of the first cutting layer CL1 or the second cutting layer CL2, but may have a different etching selectivity for the etching process depending on different deposition processes, differences in chemical composition, whether heat treatment is performed, and the like.

According to the disclosed concepts, the cutting pattern CT may include a plurality of layers, for example, the first cutting layer CL1 and the second cutting layer CL2. Since the first cutting layer CL1 and the second cutting layer CL2 have different etching selectivities with respect to the etching process, a width of the cutting pattern CT may be reduced by removing the portion of the first cutting layer CL1 when the cutting pattern CT is formed. For this reason, there may be a change in widths between the first portion PT1 from which the first cutting layer CL1 has not been removed and the second portion PT2 from which the first cutting layer CL1 has been removed. Accordingly, the width of the cutting pattern CT is reduced, so that a size of the transistor can be reduced. As a result, a reliability and electrical characteristics of the semiconductor device can be improved.

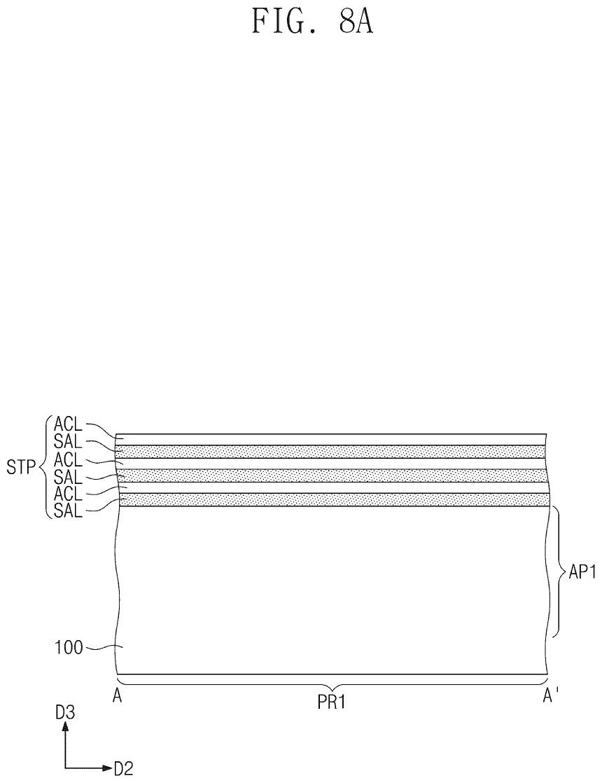

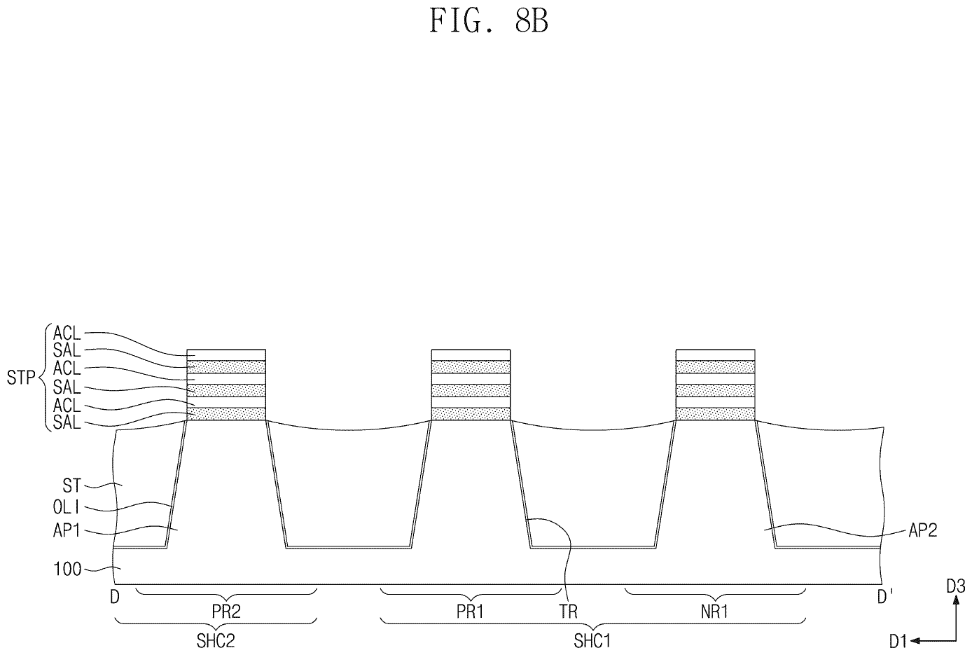

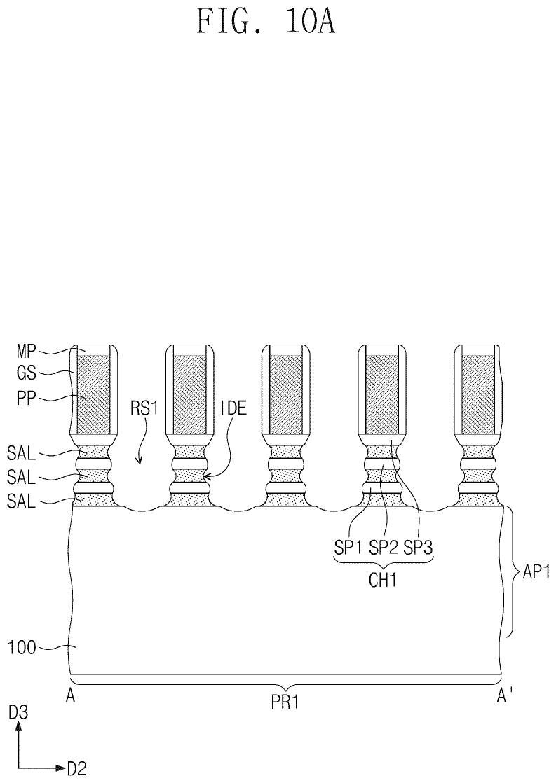

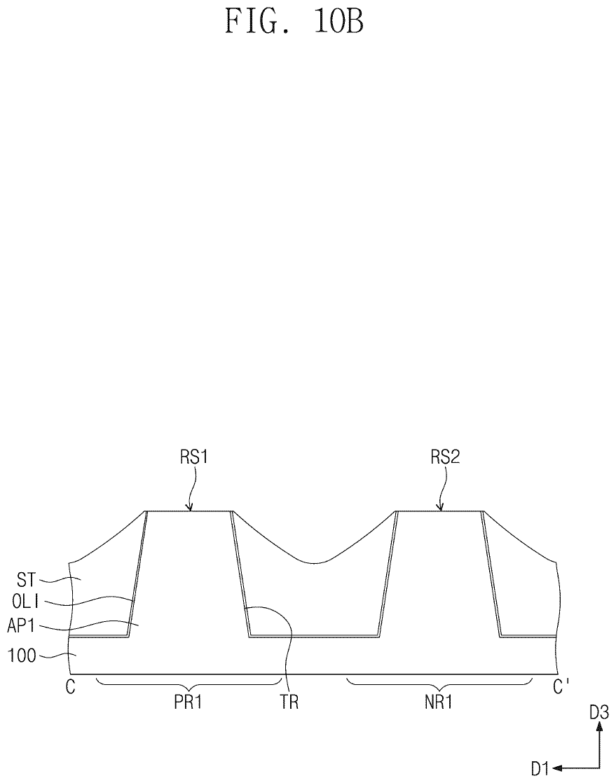

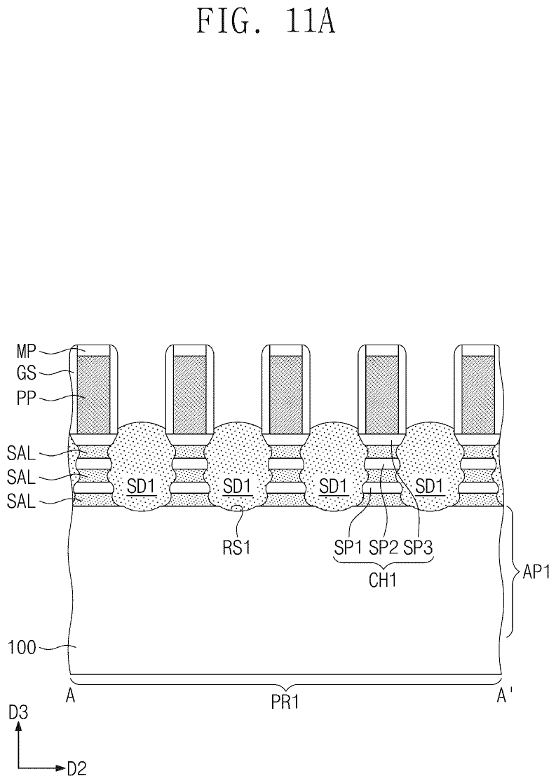

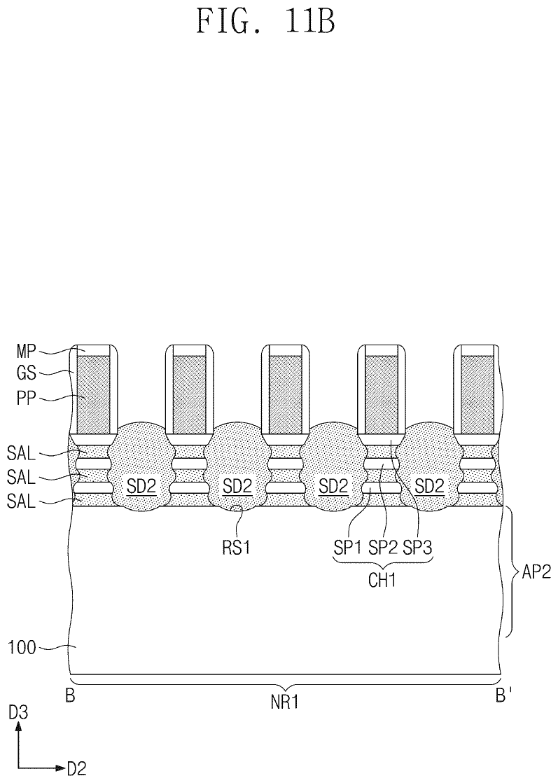

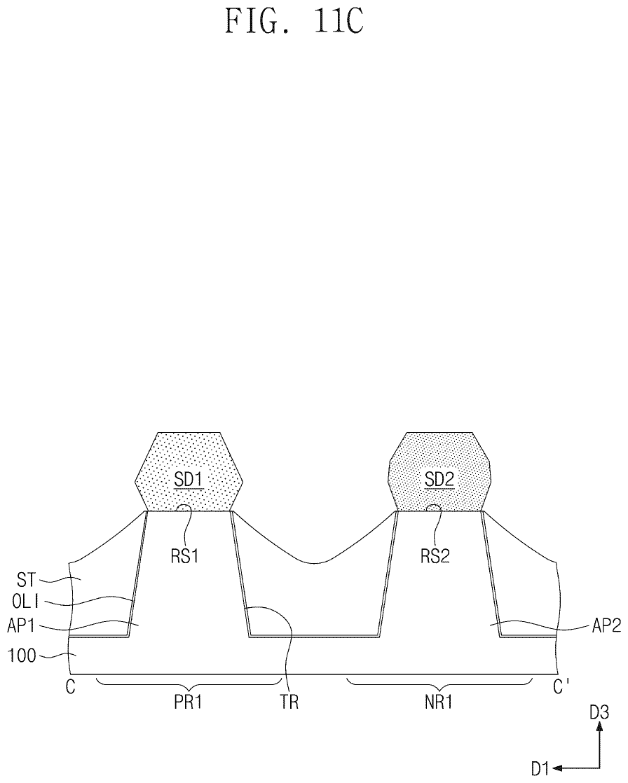

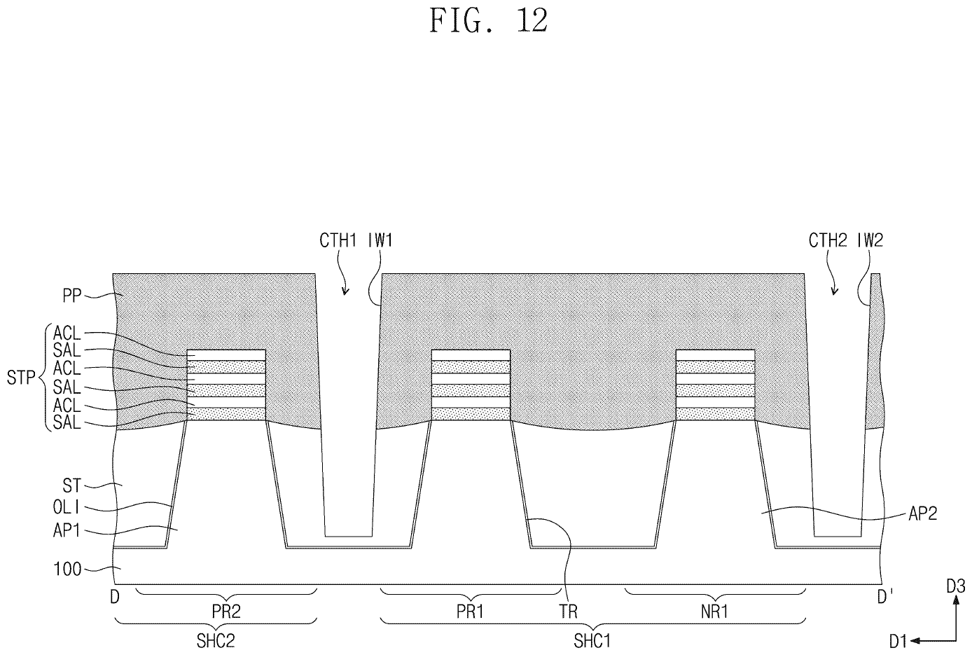

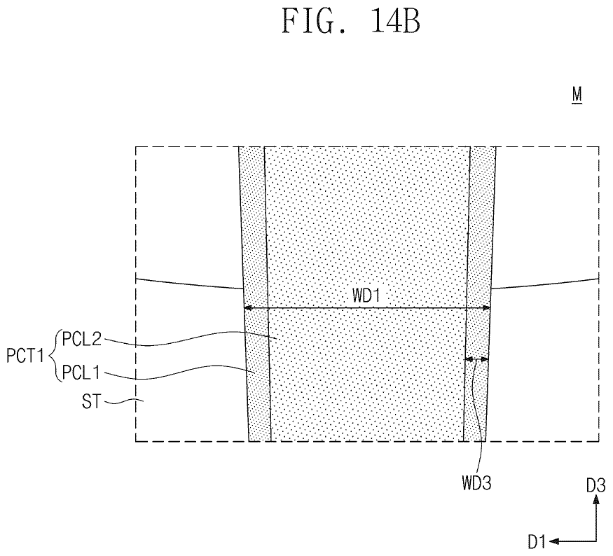

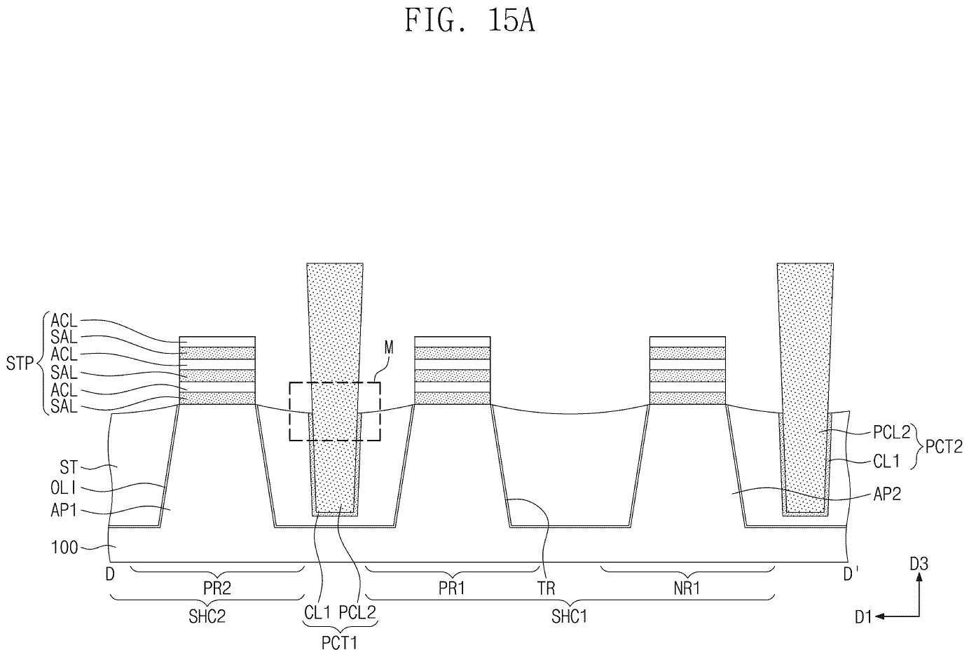

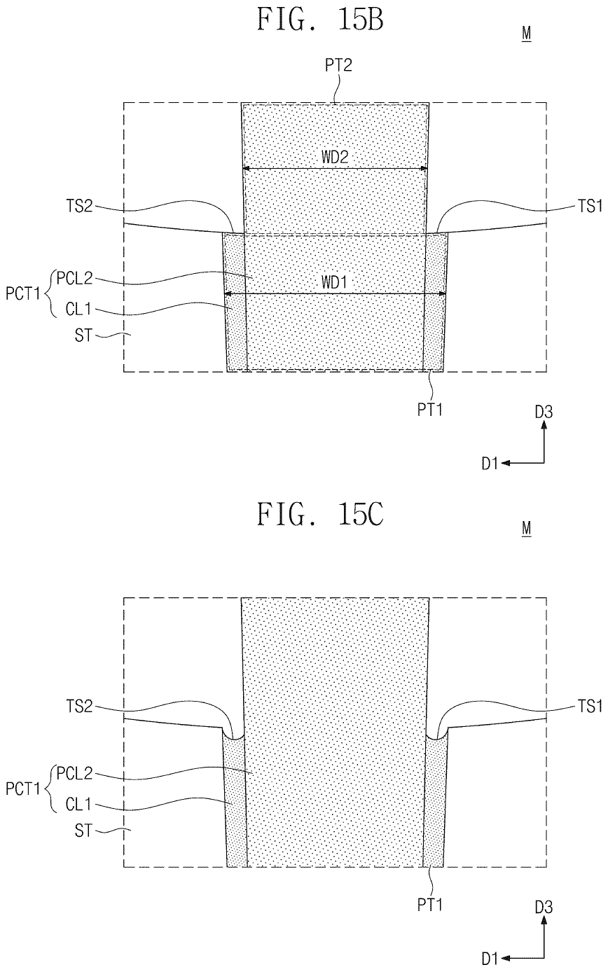

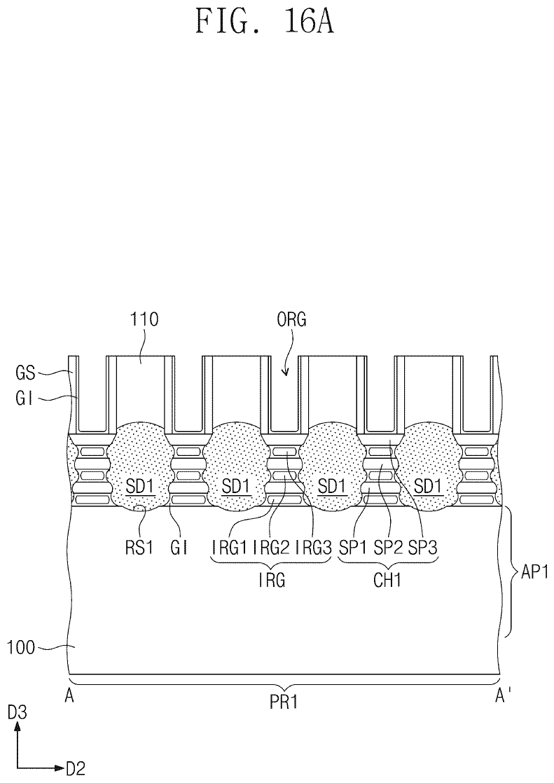

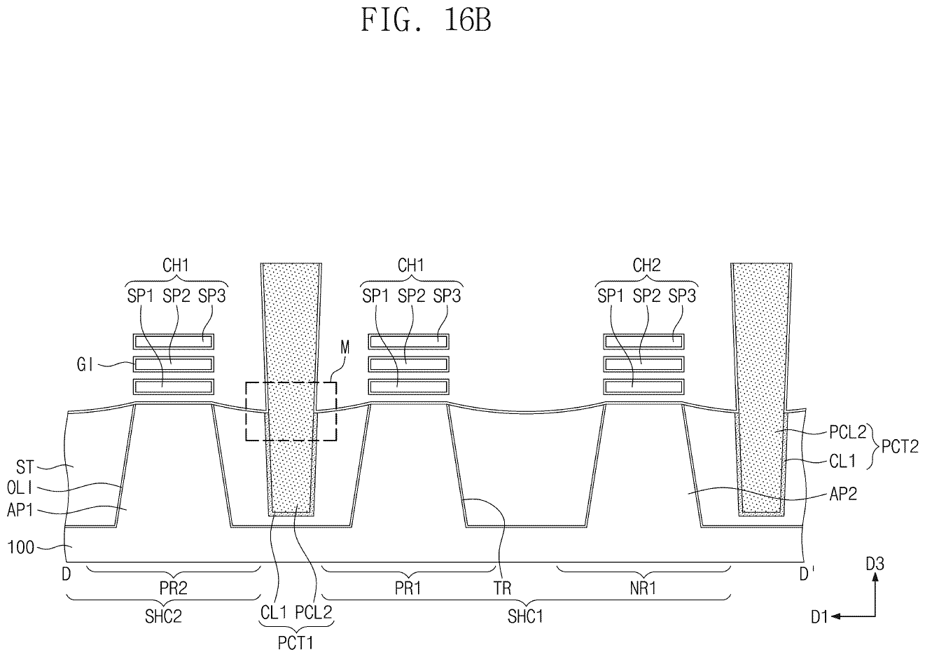

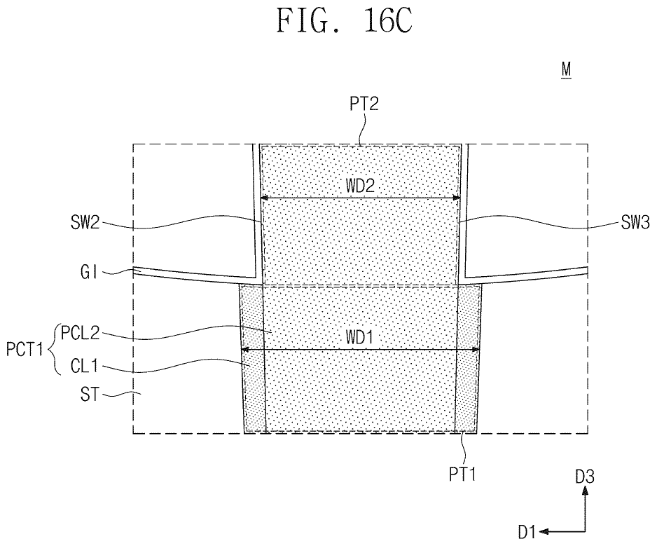

FIGS. 8A, 8B, 9, 10A, 10B, 11A, 11B, 11C, 12, 13, 14A, 14B, 15A, 15B, 15C, 16A, 16B, 16C, 17A, 17B and 17C are diagrams for describing a method of manufacturing a semiconductor device according to embodiments of the disclosed concepts. In detail, FIGS. 8A, 9A, 10A, 11A, 16A, and 17A are cross-sectional views taken along line A-A′ of FIG. 4. FIG. 11B is a cross-sectional view taken along line B-B′ of FIG. 4. FIGS. 10B, 11C and 17B are cross-sectional views taken along line C-C′ of FIG. 4. FIGS. 8B, 12, 13, 14A, 15A, 16B and 17C are cross-sectional taken along line D-D′ of FIG. 4. FIG. 14B is an enlarged view illustrating the portion M of FIG. 14A. FIG. 15B is an enlarged view of embodiments of the portion M of FIG. 15A, and FIG. 15C is an enlarged view illustrating embodiments of the portion M of FIG. 15A. FIG. 16C is an enlarged view illustrating the portion M of FIG. 16B.

A method for manufacturing a semiconductor element of the disclosed concepts will be described in detail with reference to FIGS. 8A to 17C.

Referring to FIGS. 8A and 8B, a substrate 100 including the first PMOSFET region PR1, the second PMOSFET regions PR2, the first NMOSFET region NR1, and the second NMOSFET region NR2 may be provided. Active layers ACL and sacrificial layers SAL alternately may be stacked on the substrate 100. The active layers ACL may include one of silicon (Si), germanium (Ge), and silicon-germanium (SiGe), and the sacrificial layers SAL may include another one of silicon (Si), germanium (Ge), and silicon-germanium (SiGe).

The sacrificial layer SAL may include a material that may have an etch selectivity with respect to the active layer ACL. For example, the active layers ACL may include silicon (Si), and the sacrificial layers SAL may include silicon-germanium (SiGe). The concentration of germanium (Ge) in each of the sacrificial layers SAL may be 10 at % to 30 at %.

Mask patterns may be formed on the first and second active patterns AP1 and AP2 of the substrate 100, respectively. The mask pattern may have a line shape or a bar shape extending in the second direction D2.

The trench TR defining the first active pattern AP1 and the second active pattern AP2 may be formed by performing a patterning process on the mask patterns with an etching mask. The first active patterns AP1 may be formed on each of the first and second PMOSFET regions PR1 and PR2. The second active patterns AP2 may be formed on each of the first and second NMOSFET regions NR1 and NR2.

A stacked pattern STP may be formed on each of the first and second active patterns AP1 and AP2. The stacked pattern STP may include the active layers ACL and the sacrificial layers SAL alternately stacked with one another. The stacked pattern STP may be formed together with the first and second active patterns AP1 and AP2 during the patterning process.

The liner layer OLI may be formed on the trench TR. The liner layer OLI may include an insulating material such as a silicon nitride layer, a silicon oxide layer, and/or a combination thereof. The device isolation layer ST may be formed to fill the trench TR. For example, an insulating layer covering the first and second active patterns AP1 and AP2 and the stacked patterns STP may be formed on a front surface of the substrate 100. The insulating layer is recessed until the stacked patterns STP are exposed, so that the device isolation layer ST may be formed.

The device isolation layer ST may include an insulating material such as silicon oxide. The stacked patterns STP may be exposed on the device isolation layer ST. In other words, the stacked patterns STP may protrude vertically from the device isolation layer ST.

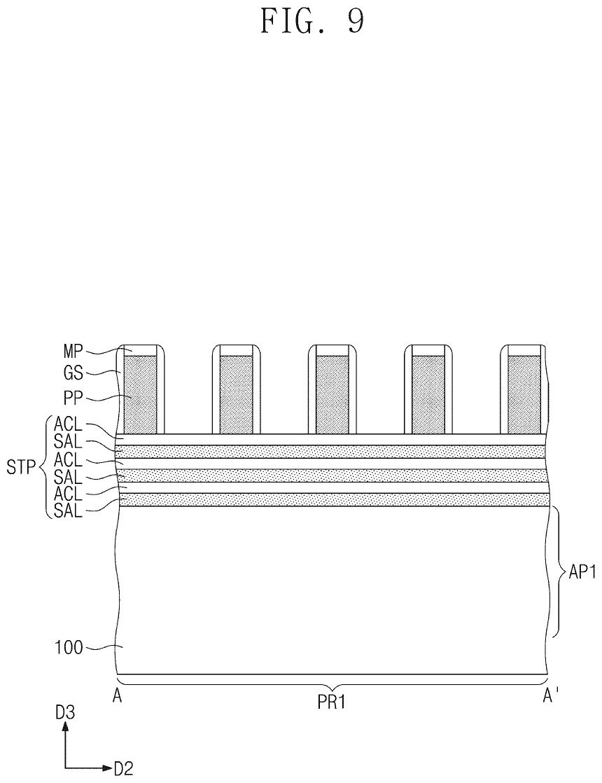

Referring to FIG. 9, sacrificial patterns PP crossing the stacked patterns STP may be formed on the substrate 100. Each of the sacrificial patterns PP may be formed in a line shape or a bar shape extending in the first direction D1. The sacrificial patterns PP may be arranged along the second direction D2 at the first pitch.

Specifically, forming the sacrificial patterns PP may include forming a sacrificial layer on the front surface of the substrate 100, forming hard mask patterns MP on the sacrificial layer, and patterning the sacrificial layer using the hard mask patterns MP as an etching mask. The sacrificial layer may include polysilicon.

A pair of gate spacers GS may be formed on both sidewalls of each of the sacrificial patterns PP. Forming the gate spacers GS may include conformally forming a gate spacer layer on the front surface of the substrate 100, and anisotropically etching the gate spacer layer. In some embodiments of the disclosed concepts, the gate spacer GS may be a multiple layer including at least two layers.

Referring to FIGS. 10A and 10B, first recesses RS1 may be formed in the stacked pattern STP on the first active pattern AP1. Second recesses RS2 may be formed in the stacked pattern STP on the second active pattern AP2. While forming the first and second recesses RS1 and RS2, the device isolation layer ST on both sides of each of the first and second active patterns AP1 and AP2 may be further recessed (see FIG. 10B).

For example, the stacked pattern STP on the first active pattern AP1 may be etched using the hard mask patterns MP and the gate spacers GS as an etch mask to form the first recesses RS1. The first recess RS1 may be formed between a pair of sacrificial patterns PP.

In some embodiments of the disclosed concepts, forming the first recess RS1 may further include performing a selective etching process on an exposed sacrificial layers SAL. Each of the sacrificial layers SAL may be indented by the selective etching process to form an indent region IDE. Thus, the first recess RS1 may have a wavy inner wall. Sidewalls of the sacrificial layers SAL may be recessed by the indent region IDE. The second recesses RS2 in the stacked pattern STP on the second active pattern AP2 may be formed in the same manner as forming the first recesses RS1.

The first, second, and third semiconductor patterns SP1, SP2, and SP3 sequentially stacked between first recesses RS1 adjacent to one another may be formed from the active layers ACL, respectively. The first, second, and third semiconductor patterns SP1, SP2, and SP3 between the first recesses RS1 adjacent to one another may constitute the first channel pattern CH1. The first, second, and third semiconductor patterns SP1, SP2, and SP3 between the second recesses RS2 adjacent to one another may constitute the second channel pattern CH2.

Referring to FIGS. 11A, 11B, and 11C, first source/drain patterns SD1 may be formed in the first recesses RS1, respectively. For example, the first source/drain pattern SD1 may be formed by performing a first selective epitaxial growth process (e.g., a first SEG process) using an inner wall of the first recess RS1 as a seed layer. The first SEG process may include a chemical vapor deposition (CVD) process or a molecular beam epitaxy (MBE) process.

The first source/drain pattern SD1 may include a semiconductor element (e.g., SiGe) having a lattice constant greater than that of the semiconductor element of the substrate 100. During the first SEG process, impurities may be implanted in-situ. As another example, impurities may be implanted into the first source/drain pattern SD1 after the first source/drain pattern SD1 is formed. The first source/drain pattern SD1 may be doped to have a first conductivity type (e.g., p-type).

The second source/drain patterns SD2 may be formed in the second recesses RS2, respectively. For example, the second source/drain pattern SD2 may be formed by performing a second SEG process in which an inner wall of the second recess RS2 is used as a seed layer. For example, the second source/drain pattern SD2 may include the same semiconductor element (e.g., Si) as the substrate 100. The second source/drain pattern SD2 may be doped to have a second conductivity type (e.g., n-type). Inner spacers may be formed between the second source/drain pattern SD2 and the sacrificial layers SAL, respectively.

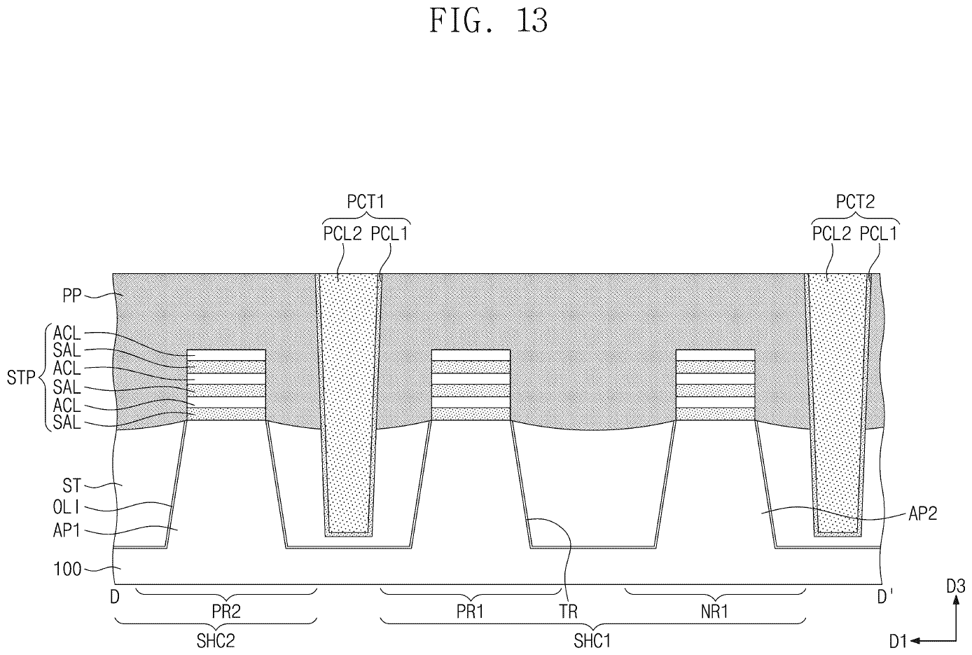

Referring to FIG. 12, a patterning process etching the sacrificial pattern PP and the device isolation layer ST may be performed on the sacrificial pattern PP to form cutting holes CTH1 and CTH2 extended in the third direction D3. Forming the cutting holes CTH1 and CTH2 may include forming a mask pattern on the sacrificial pattern PP and performing an etching process using the mask pattern as a mask to etch the sacrificial pattern PP and the device isolation layer ST. The cutting holes CTH1 and CTH2 may include a first cutting hole CTH1 between the first PMOSFET region PR1 and the second PMOSFET region PR2 and a second cutting hole CTH2 between the first NMOSFET region NR1 and the second NMOSFET region NR2.

The first and second cutting holes CTH1 and CTH2 may extend into the device isolation layer ST through the sacrificial pattern PP. An inner wall of the sacrificial pattern PP and an inner wall of the device isolation layer ST may be exposed by the first and second cutting holes CTH1 and CTH2. For example, the first cutting hole CTH1 may have a first inner wall IW1 that exposes the sacrificial pattern PP and the device isolation layer ST, and the second cutting hole CTH2 may have a second inner wall IW2 that exposes the sacrifice pattern PP and the device isolation layer ST.

In some embodiments, the first and second cutting holes CTH1 and CTH2 may penetrate the device isolation layer ST to expose the substrate 100. The first and second cutting holes CTH1 and CTH2 may have a high aspect ratio. Thus, the first and second cutting holes CTH1, CTH2 may have a relatively large depth relative to their width. The ratio of the depth to the width of the first and second cutting holes CTH1 and CTH2 may be 4 to 8, but is not limited thereto.

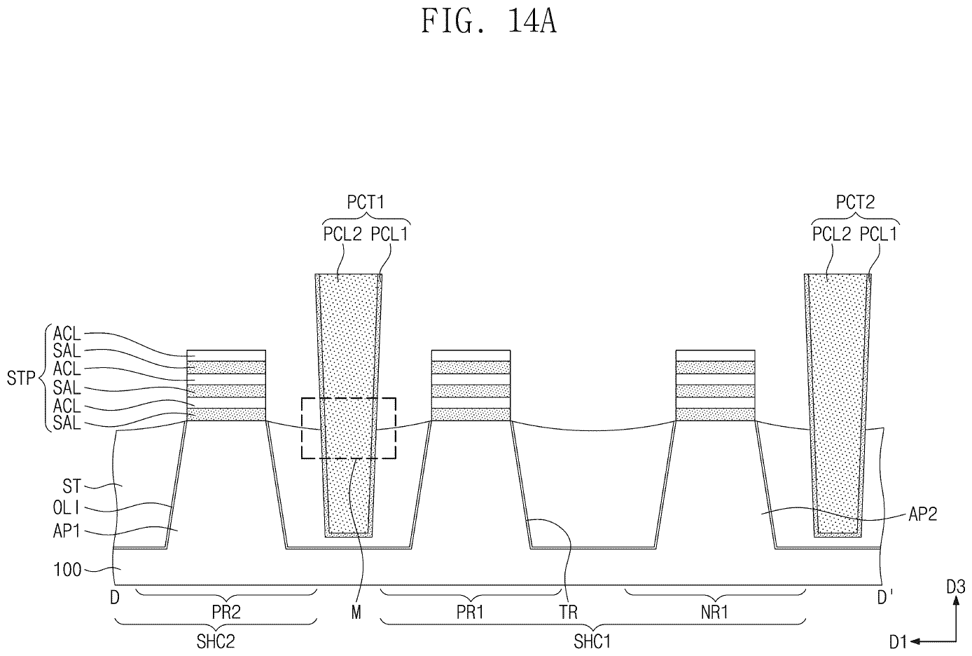

Referring to FIG. 13, a first preliminary cutting layer PCL1 and a second preliminary cutting layer PCL2 may be sequentially formed in the first and second cutting holes CTH1 and CTH2, so that first and second preliminary cutting patterns PCT1 and PCT2 may be formed.

The first preliminary cutting layer PCL1 may be formed on an inner wall of the first and second cutting holes CTH1 and CTH2. The second preliminary cutting layer PCL2 may fill the rest of the first and second cutting holes CTH1 and CTH2, and may be formed on the first preliminary cutting layer PCL1. The first preliminary cutting layer PCL1 may cover a bottom surface and both sidewalls of the second preliminary cutting layer PCL2.

The first preliminary cutting layer PCL1 and the second preliminary cutting layer PCL2 may have different etch selectivities for at least one etching process. The first preliminary cutting layer PCL1 and the second preliminary cutting layer PCL2 may be formed by different deposition processes from one another.

As described with reference to FIG. 6A, the first preliminary cutting layer PCL1 and the second preliminary cutting layer PCL2 may include the same material or may include different materials. Even when the first preliminary cutting layer PCL1 and the second preliminary cutting layer PCL2 include the silicon nitride (SiN), they may have a different etching selectivity for an etching process to be described later. This is because the first preliminary cutting layer PCL1 and the second preliminary cutting layer PCL2 may have different physical properties such as density, crystallinity, and whether deposition process and/or heat treatment are performed. The first and second preliminary cutting layers PCL1 and PCL2 may include an insulating material such as a silicon nitride layer, a silicon oxide layer, or a combination thereof.

A first interlayer insulating layer 110 may be formed on the first and second source/drain patterns SD1 and SD2, the hard mask patterns MP, and the gate spacers GS (see FIG. 16A). For example, the first interlayer insulating layer 110 may include a silicon oxide layer. The first interlayer insulating layer 110 may be planarized until upper surfaces of the sacrificial patterns PP are exposed. The planarization of the first interlayer insulating layer 110 may be performed using an etch back or a CMP (Chemical Mechanical Polishing) process. During the planarization process, all of the hard mask patterns MP may be removed.

Referring to FIGS. 14A and 14B, an etching process may be performed to selectively remove the sacrificial patterns PP on the substrate 100. The etching process may be a wet etching process. The first and second preliminary cutting layers PCL1 and PCL2 may include a material having an etch selectivity with respect to the sacrificial pattern PP and may not be removed by the etching process. While the sacrificial pattern PP is removed, a portion of sidewalls of the first preliminary cutting layer PCL1 may be exposed. For example, the first preliminary cutting layer PCL1 in the device isolation layer ST is not exposed, and the remaining portions thereof may be exposed.

The first and second preliminary cutting layers PCL1 and PCL2 may have the first width WD1, and the first preliminary cutting layer PCL1 may have the third width WD3. The third width WD3 of the first preliminary cutting layer PCL1 may be smaller than the width of the second preliminary cutting layer PCL2.

Referring to FIGS. 15A and 15B, an etching process may be performed to selectively remove the first preliminary cutting layer PCL1 exposed by the device isolation layer ST in FIG. 14A. The second preliminary cutting layer PCL2 may not be removed because it has different etching selectivity with respect to the etching process from the first preliminary cutting layer PCL1. In addition, the portion of the first preliminary cutting layer PCL1 that is not exposed by the device isolation layer ST may not be removed. The etching process may be a wet etch process. For example, the wet etching process may use, but is not limited to, a hydrofluoric acid (Hf) solution or a phosphoric acid (H3PO4) solution.

The first cutting layer CL1 may be formed while the portion of the first preliminary cutting layer PCL1 is removed. A region in which a width of the first preliminary cutting pattern PCT1 changes may be formed while the portion of the first preliminary cutting layer PCL1 is removed. The width of the first preliminary cutting pattern PCT1 may abruptly change from the first width WD1 to the second width WD2 at a boundary between the portion from which the first preliminary cutting layer PCL1 is removed and a portion from which the first preliminary cutting layer PCL1 is not removed. A portion having the first width WD1 may be the first portion PT1, and a portion having the second width WD2 may be the second portion PT2.

The first cutting layer CL1 may include a first upper surface TS1 and a second upper surface TS2, which are exposed upper surfaces. The first upper surface TS1 and the second upper surface TS2 may be coplanar with the upper surface of the device isolation layer ST, but are not limited thereto. In some embodiments, the first upper surface TS1 and the second upper surface TS2 may be higher or lower than the upper surface of the device isolation layer ST.

According to the disclosed concepts, the first preliminary cutting layer PCL1 and the second preliminary cutting layer PCL2 may be sequentially formed. Then, the width of the cutting patterns CT1 and CT2 may be reduced by removing the portion of the first preliminary cutting layer PCL1.

Referring to FIG. 15C, the second upper surface TS2 may have a concave profile. This is because the first preliminary cutting layer PCL1 may be etched deeper than the upper surface of the device isolation layer ST in the etching process. This is because the first upper surface TS1 and the second upper surface TS2, which are exposed upper surfaces of the first cutting layer CL1, may be further etched by the etching process. Therefore, the level of each of the first upper surface TS1 and the second upper surface TS2 may be lower than the level of the upper surface of the device isolation layer ST.

In some embodiments, only one of the first upper surface TS1 and the second upper surface TS2 may have a concave profile. For example, the first upper surface TS1 may extend in the first direction D1 as shown in FIG. 15B, and the second upper surface TS2 may have a profile recessed inward of the first cutting layer CL1 as shown in FIG. 15C.

Referring to FIGS. 16A, 16B, and 16C, the sacrificial layers SAL may be exposed by removing the sacrificial pattern PP. An exposed sacrificial layers SAL may be selectively removed by an etching process. The etching process may be a wet etching process. An etching material used in the etching process may quickly remove the sacrificial layer SAL having a relatively high germanium concentration. The first, second, and third semiconductor patterns SP1, SP2, and SP3 may be exposed while the sacrificial layers SAL are removed.

The gate insulating layer GI may be formed on the exposed first, second, and third semiconductor patterns SP1, SP2, and SP3. The gate insulating layer GI may surround each of the first, second, and third semiconductor patterns SP1, SP2, and SP3. The gate insulating layer GI may be formed in each of first, second, and third inner regions IRG1, IRG2, and IRG3. The gate insulating layer GI may be formed in an outer region ORG.

The gate insulating layer GI may be formed on the upper surfaces of the first and second active patterns AP1 and AP2 and the upper surface of the device isolation layer ST. The gate insulating layer GI may be formed on the exposed first upper surface TS1 and the second upper surface TS2, and may extend in the third direction D3 along both sidewalls SW2 and SW3 of the first preliminary cutting pattern PCT1. In other words, the gate insulating layer GI may be formed on the sidewalls SW2 and SW3 of the first preliminary cutting pattern PCT1.

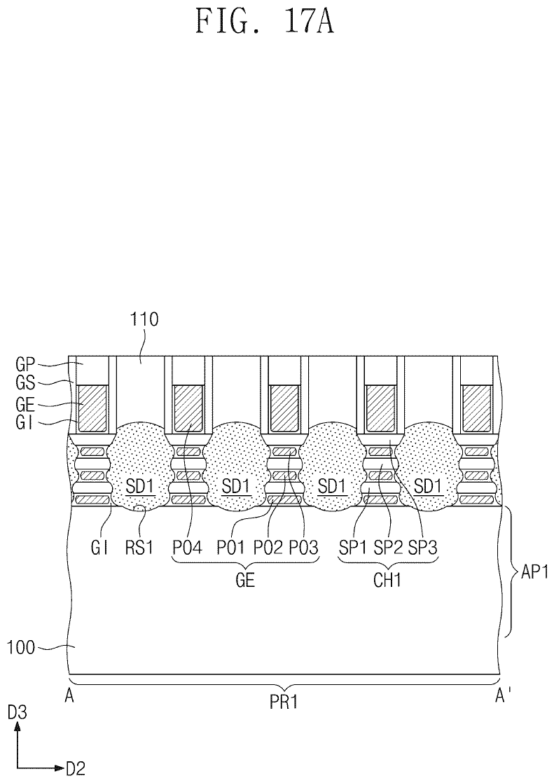

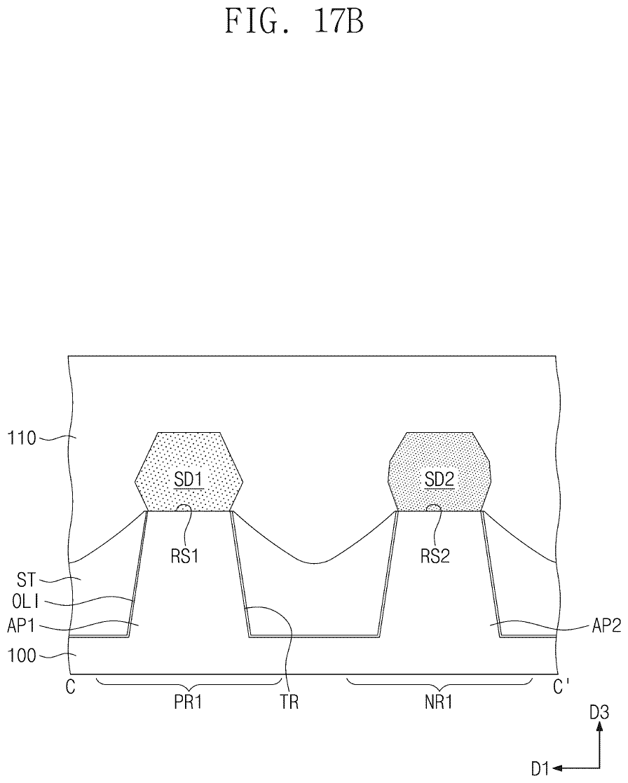

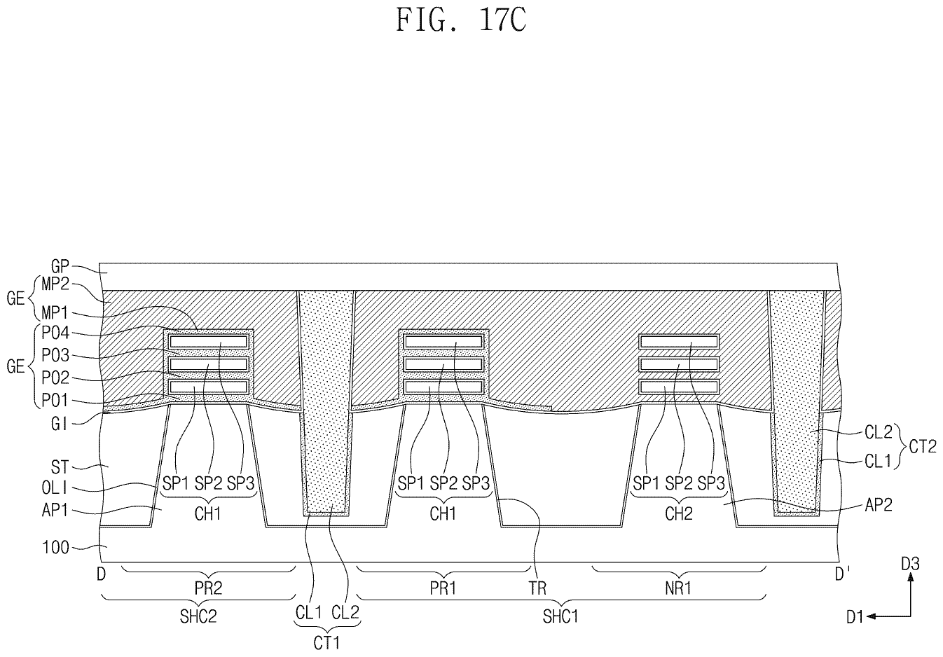

Referring to FIGS. 17A, 17B, and 17C, the gate electrode GE may be formed on the gate insulating layer GI. The gate electrode GE may include first, second, and third inner portions PO1, PO2, and PO3 formed in the first, second, and third inner regions IRG1, IRG2, and IRG3, respectively, and the fourth inner portion PO4 formed in the outer region ORG. The gate electrode GE may be recessed to reduce its height. The gate capping pattern GP may be formed on the recessed gate electrode GE.

As the gate electrode GE is recessed, the height of the first preliminary cutting pattern PCT1 may be reduced to form the first cutting pattern CT1. Forming the second cutting pattern CT2 may be substantially the same as forming the first cutting pattern CT1 described above. The gate capping pattern GP may be formed on the first cutting pattern CT1 and the second cutting pattern CT2. The upper surface of each of the first cutting pattern CT1 and the second cutting pattern CT2 may be in contact with a bottom surface of the gate capping pattern GP.

Forming the gate electrode GE on the first and second PMOSFET regions PR1 and PR2 may include sequentially forming the first metal pattern MP1 and the second metal pattern MP2. The first metal pattern MP1 may be formed on the gate insulating layer GI, and the second metal pattern MP2 may be formed on each of the first metal patterns MP1. The first metal pattern MP1 may fill all of the first, second, and third inner regions IRG1, IRG2, and IRG3, and may also be formed in a portion of the outer region ORG. The first metal pattern MP1 may surround the first, second, and third semiconductor patterns SP1, SP2, and SP3. Referring to FIG. 6A, the first metal pattern MP1 may also be formed on a portion of the sidewall of the first cutting pattern CT1 by extending onto the device isolation layer ST.

Referring again to FIGS. 4 and 5A, 5B, 5C and 5D, the second interlayer insulating layer 120 may be formed on the first interlayer insulating layer 110. The second interlayer insulating layer 120 may include silicon oxide. The active contacts AC electrically connected to the first and second source/drain patterns SD1 and SD2 may be formed through the second interlayer insulating layer 120 and the first interlayer insulating layer 110. The gate contact GC electrically connected to the gate electrode GE may be formed through the second interlayer insulating layer 120 and the gate capping pattern GP.

Forming each of the active contact AC and the gate contact GC may include forming the barrier pattern BM and forming the conductive pattern FM on the barrier pattern BM. The barrier pattern BM may include a metal layer/metal nitride. The conductive pattern FM may include a low-resistance metal.

The separation structures DB may be formed at the first boundary BD1 and the second boundary BD2 of the single height cell SHC, respectively. The separation structure DB may extend into the first and second active patterns AP1 and AP2 through the gate capping pattern GP and the gate electrode GE. The separation structure DB may include an insulating material such as silicon oxide or silicon nitride.

The third interlayer insulating layer 130 may be formed on the active contacts AC and the gate contacts GC. The first metal layer M1 may be formed in the third interlayer insulating layer 130. The fourth interlayer insulating layer 140 may be formed on the third interlayer insulating layer 130. The second metal layer M2 may be formed in the fourth interlayer insulating layer 140.

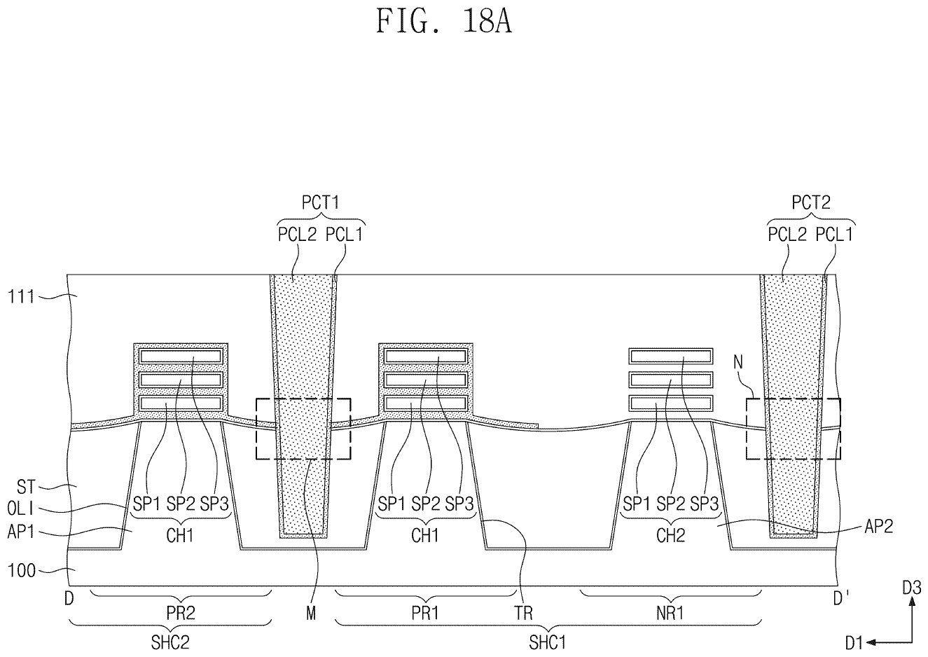

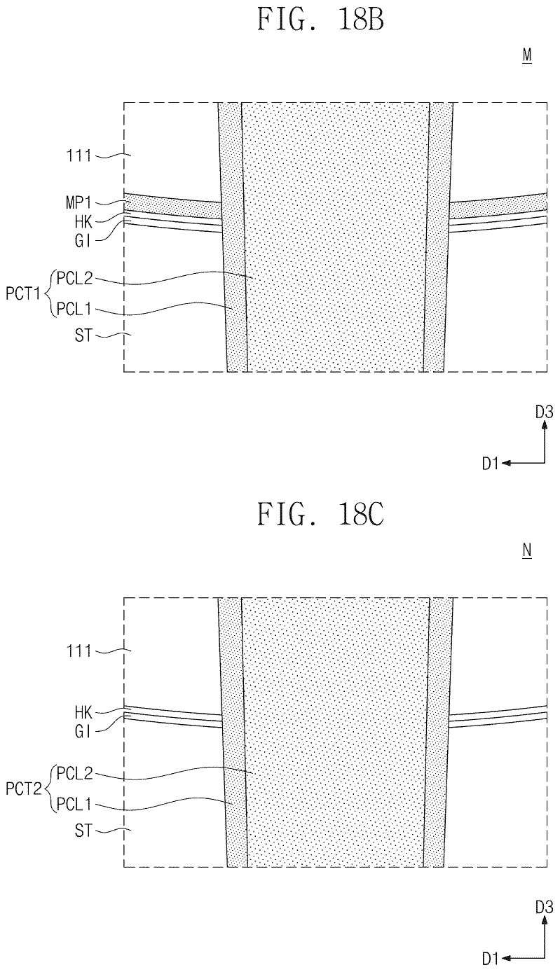

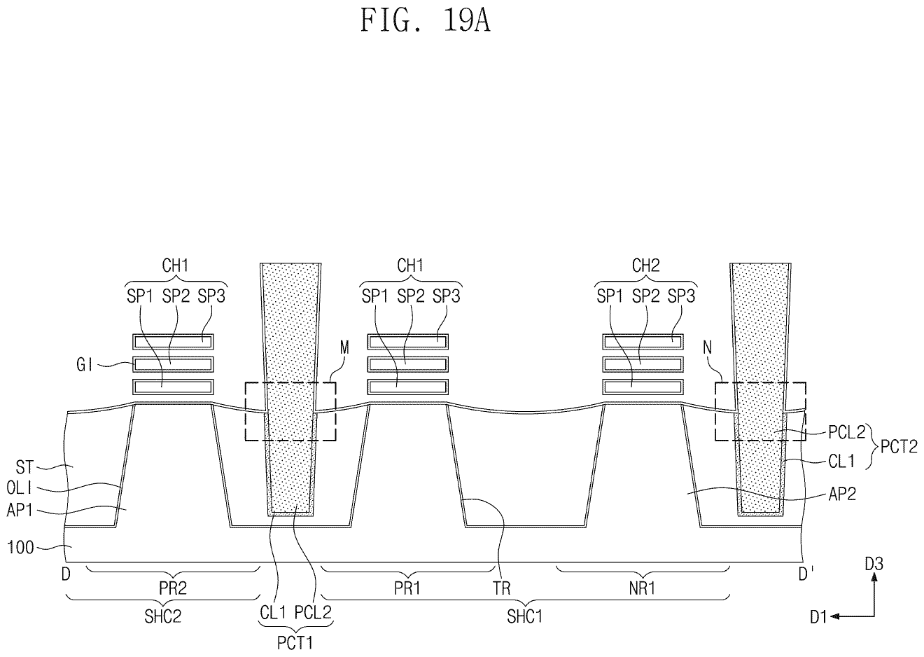

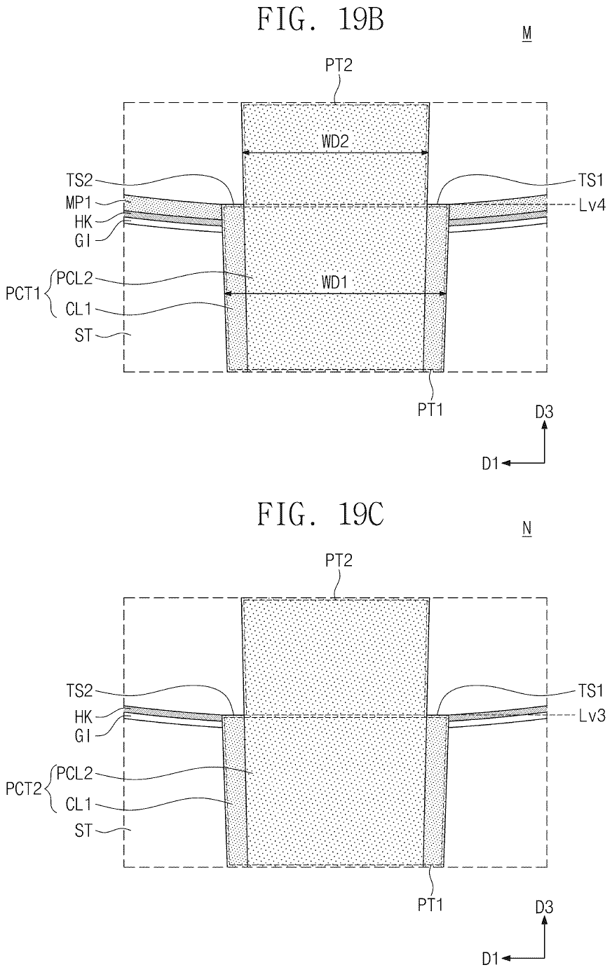

FIGS. 18A, 18B, 18C, 19A, 19B and 19C are diagrams for describing a method of manufacturing a semiconductor device according to embodiments of the disclosed concepts. The technical features that overlap with those described with reference to FIGS. 8A to 17C are omitted, and the differences are described in detail.

FIGS. 18A and 19A are cross-sectional view taken along line D-D′ of FIG. 4. FIG. 18B is an enlarged view illustrating the portion M of FIG. 18A. FIG. 18C is an enlarged view indicating the portion N of FIG. 18A. FIG. 19B is an enlarged view illustrating the portion M of FIG. 19A. FIG. 19C is an enlarged view indicating the portion N of FIG. 19A.

Referring to FIGS. 18A, 18B, and 18C, the first and second source/drain patterns SD1 and SD2 may be formed according to FIGS. 11A, 11B and 11C. An etching process may then be performed to selectively remove the sacrificial patterns PP. By removing the sacrificial patterns PP, the outer region ORG may expose the first and second channel patterns CH1 and CH2 (see FIG. 16A). Removing the sacrificial patterns PP may include wet etching using an etchant that selectively etches the polysilicon.

The sacrificial layers SAL exposed through the outer region ORG may be selectively removed to form the first, second, and third inner regions IRG1, IRG2, and IRG3 (see FIG. 16A). For example, an etching process of selectively etching the sacrificial layers SAL may be performed to remove only the sacrificial layers SAL while the first, second, and third semiconductor patterns SP1, SP2, and SP3 remain. The etching process may have a high etch rate for silicon germanium having a relatively high germanium concentration.

The gate insulating layer GI may be formed on the exposed first, second, and third semiconductor patterns SP1, SP2, and SP3. The gate insulating layer GI may surround each of the first, second, and third semiconductor patterns SP1, SP2, and SP3. The gate insulating layer GI may be formed in each of the first, second, and third inner regions IRG1, IRG2, and IRG3. The gate insulating layer GI may be formed in the outer region ORG.

The first metal pattern MP1 may be formed on the gate insulating layer GI in the first and second PMOSFET regions PR1 and PR2. The first metal pattern MP1 may extend to the upper surface of the device isolation layer ST on the first and second PMOSFET regions PR1 and PR2.

A sacrificial insulating layer 111 may be formed on the front surface of the substrate 100. The sacrificial insulating layer 111 may be formed on the device isolation layer ST, the first and second active patterns AP1 and AP2, and the first, second, and third semiconductor patterns SP1, SP2, and SP3. The sacrificial insulating layer 111 may include an insulating material.

A patterning process may be performed on the sacrificial insulating layer 111 to form the first and second cutting holes CTH1 and CTH2 as shown in FIG. 12. The first and second cutting holes CTH1 and CTH2 may extend into the device isolation layer ST through the sacrificial insulating layer 111. An inner wall of the sacrificial insulating layer 111 and an inner wall of the device isolation layer ST may be exposed by the first and second cutting holes CTH1 and CTH2.

Then, the first preliminary cutting layer PCL1 and the second preliminary cutting layer PCL2 may be sequentially formed in the first and second cutting holes CTH1 and CTH2. Forming the first preliminary cutting layer PCL1 and the second preliminary cutting layer PCL2 may be substantially the same as described with reference to FIG. 13. However, referring to FIGS. 18B and 18C, since the gate insulating layer GI, the high dielectric layer HK, and the first metal pattern MP1 are formed before the first preliminary cutting layer PCL1 and the second preliminary cutting layer PCL2, the gate insulating layer GI, the high dielectric layer HK and the first metal patterns MP1 may be in contact with the sidewalls of the first preliminary cutting layer PCL1.

Referring to FIGS. 19A, 19B, and 19C, an etching process may be performed to selectively remove the sacrificial insulating layer 111. The first preliminary cutting layer PCL1 may include a material having an etching selectivity with respect to the sacrificial insulating layer 111 and may not be removed by the etching process. While the sacrificial insulating layer 111 is removed, a portion of the sidewalls of the first preliminary cutting layer PCL1 may be exposed. For example, the first preliminary cutting layer PCL1 located below the first metal pattern MP1 of the first and second PMOSFET regions PR1 and PR2 may not be exposed, and the remaining portions thereof may be exposed. The first preliminary cutting layer PCL1 located below the high dielectric layer HK of the first and second NMOSFET regions NR1 and NR2 is not exposed, and the remaining portions thereof may be exposed.

An etching process may be performed to selectively remove an exposed first preliminary cutting layer PCL1. The second preliminary cutting layer PCL2 may not be removed because it has different etching selectivity with respect to the etching process from the first preliminary cutting layer PCL1. In addition, portions not exposed by the first metal pattern MP1 or the high dielectric layer HK may not be removed.

The first cutting layer CL1 may be formed while the portion of the first preliminary cutting layer PCL1 is removed. A region in which the width of the first preliminary cutting pattern PCT1 changes may be formed while the portion of the first preliminary cutting layer PCL1 is removed. The width of the first preliminary cutting pattern PCT1 may abruptly change from the first width WD1 to the second width WD2 at the boundary between the portion from which the first preliminary cutting layer PCL1 is removed and a portion from which the first preliminary cutting layer PCL1 is not removed.

The first cutting layer CL1 may include the first upper surface TS1 and a second upper surface TS2, which are exposed upper surfaces. In the first and second PMOSFET regions PR1 and PR2, the first upper surface TS1 and the second upper surface TS2 may be located at the fourth level Lv4, and in the first and second NMOSFET regions NR1 and NR2, the first upper surfaces TS1 and second upper surfaces TS2 may also be located at the third level Lv3. Due to the thickness of the first metal pattern MP1, the fourth level Lv4 may be higher than the third level Lv3. Therefore, the level of the upper surface of the first cutting layer CL1 in the first and second PMOSFET regions PR1 and PR2 may be higher than the level of the upper surface of the first cutting layer CL1 in each of the first and second NMOSFET regions NR1 and NR2. That is, the first and second PMOSFET regions PR1 and PR2 and the second NMOSFET regions NR1 and NR2 may have different levels of upper surfaces of the first portion PT1.

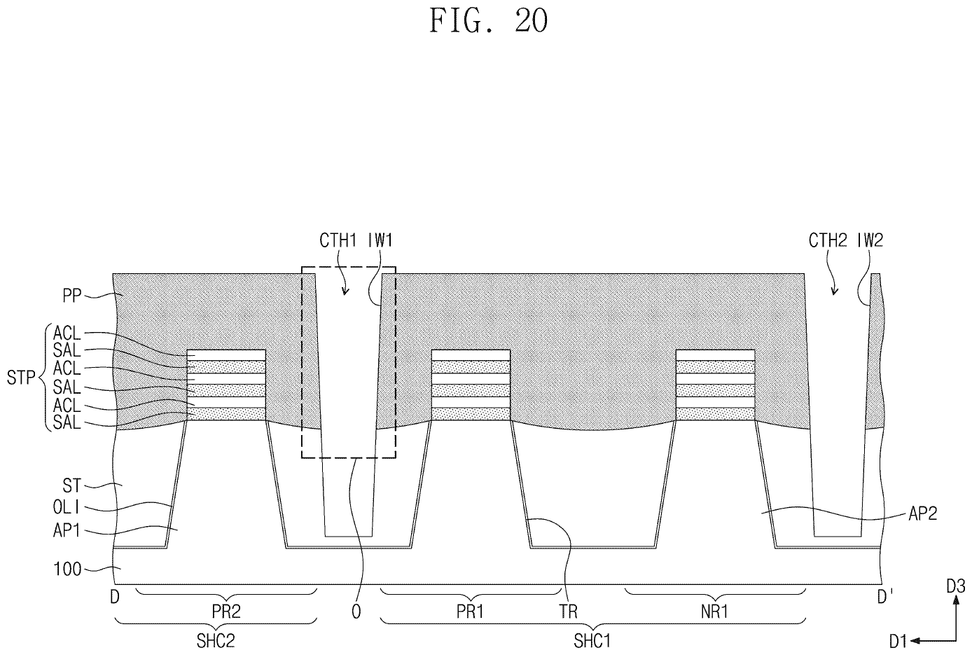

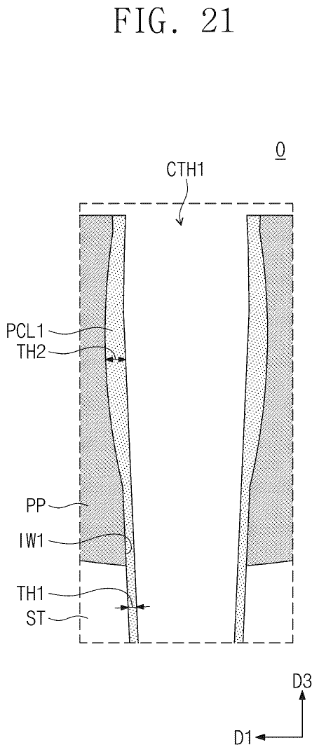

FIGS. 20 to 24 are diagrams for describing a method of manufacturing a semiconductor device according to embodiments of the disclosed concepts. FIG. 20 is a cross-sectional view taken along line D-D′ of FIG. 4. FIGS. 21, 22, 23, and 24 are enlarged views showing the portion O of FIG. 20. The technical features that overlap with those described with reference to FIGS. 8A to 17C are omitted, and the differences are described in detail.

Referring to FIGS. 20 and 21, a patterning process may be performed on the sacrificial pattern PP to form the first and second cutting holes CTH1 and CTH2 in which the sacrificial pattern PP and the device isolation layer ST are etched and extend in the third direction D3. However, unlike FIG. 12, the inner wall of the first and second cutting holes CTH1 and CTH2 may have a negative slope. Referring to FIG. 12, the widths of the first and second cutting holes CTH1 and CTH2 may decrease in a vertical direction (e.g. in the third direction D3) toward a bottom surface of the substrate 100. However, referring to FIGS. 20 and 21, there may be a section in which the width of the first and second cutting holes CTH1 and CTH2 increases in the vertical direction toward the bottom surface of the substrate 100. If the inner wall of the first and second cutting holes CTH1 and CTH2 may have a negative slope, then an air gap or seam may be formed when an insulating material is filled to form the cutting pattern CT in the first and second cutting holes CTH1 and CTH2, respectively. This is because the first and second cutting holes CTH1 and CTH2 have the large aspect ratio. This may cause a problem in that the electrical characteristics of the semiconductor element deteriorate.

On the other hand, the disclosed concepts may first form the first preliminary cutting layer PCL1 in the first and second cutting holes CTH1 and CTH2. Since the first preliminary cutting layer PCL1 is formed on the inner wall of the first and second cutting holes CTH1 and CTH2, the air gap or a seam may not be formed even in the section including the negative slope. By forming the first preliminary cutting layer PCL1, a negative slope section of the first and second cutting holes CTH1 and CTH2 may be removed.

A thickness of the first preliminary cutting layer PCL1 may not be constant. For example, a first thickness TH1 of the first preliminary cutting layer PCL1 in a section other than the negative slope section may be smaller than a second thickness TH2 of the first preliminary cutting layer PCL1 of the negative slope section.

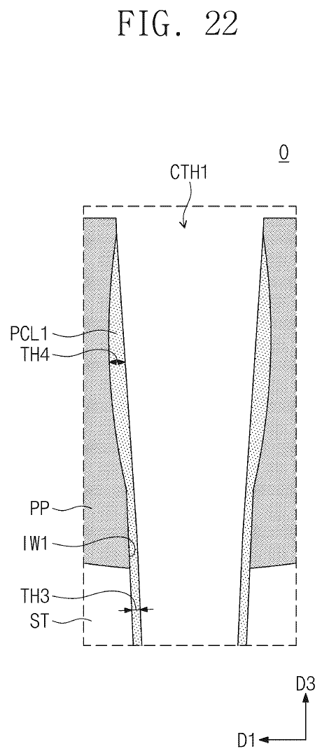

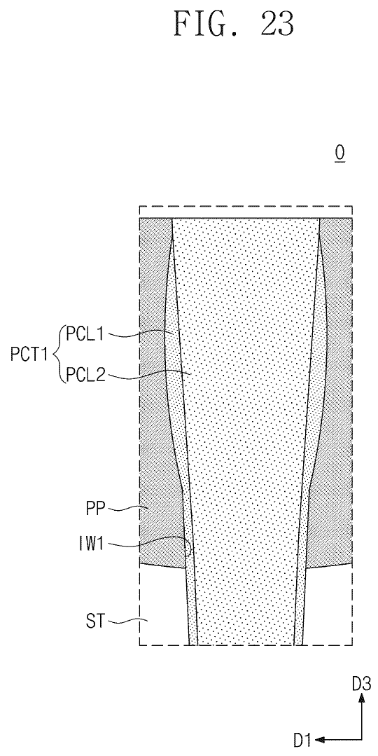

Referring to FIG. 22, after a formation of the first preliminary cutting layer PCL1, an etching process may be further performed on the first preliminary cutting layer PCL1. However, the etching process may be omitted. By the etching process, the thickness of the first preliminary cutting layer PCL1 may be reduced. For example, the second thickness TH2 of the first preliminary cutting layer PCL1 in the negative slope section may decrease to the fourth thickness TH4. The first thickness TH4 of the first preliminary cutting layer PCL1 in a section other than the negative slope section may decrease to the third thickness TH3.

By the etching process, all of the negative slope sections of the first and second cutting holes CTH1 and CTH2 may be removed. Accordingly, the widths of the first and second cutting holes CTH1 and CTH2 may decrease in the vertical direction toward the bottom surface of the substrate 100.

Referring to FIG. 23, the second preliminary cutting layer PCL2 fills a remain portion of the first and second cutting holes CTH1 and CTH2, and may be formed on the first preliminary cutting layer PCL1. The first preliminary cutting layer PCL1 may be on the bottom surface and both sidewalls of the second preliminary cutting layer PCL2. The air gap or seam may not be formed when the second preliminary cutting layer PCL2 is formed while the negative slope section is removed.

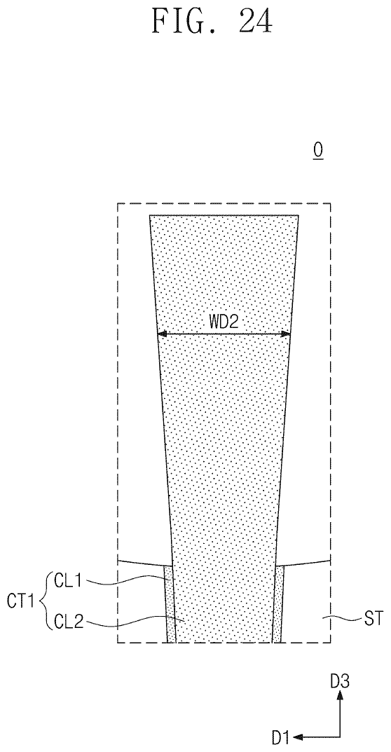

Referring to FIG. 24, an etching process may be performed to selectively remove the sacrificial pattern PP on the substrate 100. Removing the sacrificial pattern PP may be substantially the same as that described with reference to FIGS. 14A and 14B. While the sacrificial pattern PP is removed, the portion of the sidewalls of the first preliminary cutting layer PCL1 may be exposed.

Then, the exposed first preliminary cutting layer PCL1 may be selectively removed. A removal of the first preliminary cutting layer PCL1 may be substantially the same as that described with reference to FIGS. 15A and 15B. While the first preliminary cutting layer PCL1 is removed, the second preliminary cutting layer PCL2 may be exposed. Since all of the negative slope sections are removed, the second width WD2 of the second preliminary cutting layer PCL2 may decrease in the vertical direction toward the bottom surface of the substrate 100.

According to FIGS. 20 to 24, a method of manufacturing the cutting pattern CT of the disclosed concepts may include sequentially forming the first and second preliminary cutting layers PCL1 and PCL2. The negative slope sections formed in the first and second cutting holes CTH1 and CTH2 may be removed while forming and etching the first preliminary cutting layer PCL1. Accordingly, the cutting patterns CT may not include the air gap or a seam. As a result, it is possible to manufacture a semiconductor device with improved reliability and electrical characteristics.

In the three-dimensional field effect transistor according to the disclosed concepts, the width of the cutting pattern extending vertically through the gate electrode can be changed. The cutting pattern may include the first portion and the second portion on the first portion, wherein the width of the first portion at the boundary between the first portion and the second portion is greater than the width of the second portion. The first portion may include the first cutting layer and the second cutting layer having different etch selectivities for the etch process. Further, according to the method for manufacturing the cutting pattern of the disclosed concepts, the first cutting layer and the second cutting layer can be sequentially formed. The width of the cutting pattern can be reduced by removing the portion of the first cutting layer. Accordingly, the size of the transistor of the semiconductor device can be reduced, and reliability and electrical characteristics can be improved.

While embodiments are described above, a person skilled in the art may understand that many modifications and variations are made without departing from the spirit and scope of the disclosed concepts defined in the following claims. Accordingly, the example embodiments of the disclosed concepts should be considered in all respects as illustrative and not restrictive, with the spirit and scope of the disclosed concepts being indicated by the appended claims.

What is claimed is:

1. A semiconductor device comprising:
first active patterns spaced apart from one another in a first direction;
a first device isolation layer between the first active patterns adjacent to one another;
first channel patterns on the first active patterns; and
a cutting pattern extending vertically between the first channel patterns,
wherein the cutting pattern comprises a first portion and a second portion on the first portion, and
wherein a width of the first portion is greater than a width of the second portion at a boundary between the first portion and the second portion.

2. The semiconductor device of claim 1, wherein a sidewall of the first portion is spaced apart from a sidewall of the second portion in the first direction, and
wherein an upper surface of the first portion connects the sidewall of the first portion and the sidewall of the second portion.

3. The semiconductor device of claim 1, further comprising a gate insulating layer covering an upper surface of the device isolation layer,
wherein the gate insulating layer is in contact with at least one of the upper surface of the first portion or the sidewall of the first portion.

4. The semiconductor device of claim 1, further comprising a gate electrode on the first channel pattern,
wherein the upper surface of the first portion faces the gate electrode.

5. The semiconductor device of claim 4, wherein the gate electrode includes a first metal pattern on the first active pattern, and a second metal pattern on the first metal pattern, and
wherein the sidewall of the first portion is in contact with the first metal pattern.

6. The semiconductor device of claim 1, wherein the first portion includes a first cutting layer and a second cutting layer on the first cutting layer,
wherein the first cutting layer is on a sidewall of the second cutting layer, and
wherein the first cutting layer and the second cutting layer have different etch selectivities with respect to at least one etching process.

7. The semiconductor device of claim 6, wherein a level of the upper surface of the first cutting layer is lower than a level of an upper surface of the first active pattern.

8. The semiconductor device of claim 6, wherein the first cutting layer and the second cutting layer are formed by different deposition processes from one another.

9. The semiconductor device of claim 6, wherein the second portion further includes the second cutting layer and the first cutting layer on the sidewall of the second cutting layer, and
wherein a width of the first cutting layer of the second portion is less than a width of the first cutting layer of the first portion.

10. The semiconductor device of claim 6, wherein the first portion further includes a third cutting layer between the first cutting layer and the second cutting layer, and
wherein the third cutting layer has a different etch selectivity from at least one of the first cutting layer or the second cutting layer with respect to at least one etching process.

11. The semiconductor device of claim 10, wherein the second portion further includes the third cutting layer on the sidewall of the first cutting layer.

12. A semiconductor device comprising:
a substrate including a first active region and a second active region;
first active patterns spaced apart from one another in a first direction on the first active region;
a first device isolation layer between the first active patterns adjacent to one another;
a first gate electrode on the first active pattern; and
a first cutting pattern extending through the first gate electrode into the first device isolation layer,
wherein the first cutting pattern includes a first portion and a second portion on the first portion,
wherein the first portion includes a first cutting layer and a second cutting layer on the first cutting layer,
wherein the first cutting layer and the second cutting layer have different etch selectivities with respect to at least one etch process, and
wherein a sidewall of the first portion is spaced apart from a sidewall of the second portion in the first direction.

13. The semiconductor device of claim 12, wherein a level of an upper surface of the second cutting layer is lower than a level of an upper surface of the first active pattern.

14. The semiconductor device of claim 12, wherein the first portion further includes a third cutting layer between the first cutting layer and the second cutting layer, and
wherein the third cutting layer has a different etch selectivity from at least one of the first cutting layer or the second cutting layer with respect to at least one etching process.

15. The semiconductor device of claim 12, wherein the first cutting layer and the second cutting layer are formed by different deposition processes from one another.

16. The semiconductor device of claim 12, wherein the first cutting layer includes an upper surface exposed by the second cutting layer, and
wherein the upper surface of the first cutting layer faces the gate electrode.

17. The semiconductor device of claim 12, further comprising:
second active patterns spaced apart from one another in the first direction on the second active region;
a second device isolation layer between the second active patterns adjacent to one another;
a second gate electrode on the second active pattern, the second gate electrode including a first metal pattern and a second metal pattern on the first metal pattern; and
a second cutting pattern extending through the second gate electrode into the second device isolation layer,
wherein the second cutting pattern includes a third portion and a fourth portion on the third portion,
wherein the third portion includes the first cutting layer and a second cutting layer on the first cutting layer, and
wherein at least a portion of a sidewall of the third portion is in contact with the first metal pattern.

18. The semiconductor device of claim 17, wherein the first active region is an NMOSFET region and the second active region is a PMOSFET region.

19. The semiconductor device of claim 17, wherein the third portion includes an upper surface exposed by the fourth portion, and
wherein the upper surface of the third portion is higher than an upper surface of first portion.

20. A semiconductor device comprising:
a substrate including an active pattern;
a device isolation layer defining the active pattern;
first channel patterns spaced apart from one another in a first direction on the active pattern;
first source/drain patterns connected to the first channel patterns;
a cutting pattern extending vertically between the first channel patterns adjacent to one another;
a first gate electrode connected to the first source/drain patterns;
a gate insulating layer interposed between the first gate electrode and each of the first channel patterns;
a gate spacer on a sidewall of the first gate electrode;
a gate capping pattern on an upper surface of the first gate electrode;
an interlayer insulating layer on the first source/drain pattern and the gate capping pattern;
an active contact connected to each of the first source/drain patterns through the interlayer insulating layer;
a gate contact connected to the gate electrode through the gate capping pattern and the interlayer insulating layer; and
a first metal layer on the interlayer insulating layer, the first metal layer including a first wiring connected to the active contact and the gate contact,
wherein the cutting pattern includes a first portion and a second portion on the first portion,
wherein the first portion includes an upper surface exposed by the second portion, and
wherein a level of the upper surface of the first portion is lower than a level of an upper surface of the active pattern.
